(19) United States
(12) Patent Application Publication
(10) Pub. No.: US 2026/0037428 A1
(43) Pub. Date: Feb. 5, 2026

(54) MEMORY CONTROLLER, DEVICE, SYSTEM, OPERATING METHOD THEREOF, AND STORAGE MEDIUM

(71) Applicant: Yangtze Memory Technologies Co., Ltd., Wuhan (CN)

(72) Inventors: Xingwei TANG, Wuhan (CN); Zhuqin DUAN, Wuhan (CN); Wen LUO, Wuhan (CN); He LIU, Wuhan (CN); Kun REN, Wuhan (CN); Fang MA, Wuhan (CN)

(21) Appl. No.: 19/025,104

(22) Filed: Jan. 16, 2025

(30) Foreign Application Priority Data
Aug. 1, 2024 (CN) 202411053724.2

(51) Int. Cl. G06F 12/02

(52) U.S. Cl. CPC G06F 12/0246; G06F 2212/7205

(57) ABSTRACT

The embodiment of the present disclosure provides a memory controller, device, system, and method. The memory controller includes an interface and a processor, wherein the processor is configured to: obtain a statistical result of a physical page corresponding to a first read voltage, wherein the statistical result includes at least one of a first number of bits flipped in two read results of the physical page corresponding to the first read voltage and a read voltage whose voltage difference with the first read voltage is less than a preset voltage, or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

### CROSS-REFERENCE TO RELATED APPLICATIONS

This application claims priority to Chinese Patent Application No. 202411053724.2, filed on Aug. 1, 2024, which is hereby incorporated by reference in its entirety.

### TECHNICAL FIELD

Embodiments of the present disclosure relate to the field of semiconductor technologies, and in particular, to a memory controller, a device, a system, an operating method thereof, and a storage medium.

### BACKGROUND

Memory devices are storage devices in modern information technology for storing information. As a typical non-volatile semiconductor memory, Not-And (NAND) type memory gradually becomes a mainstream product in the storage market due to its high storage density, controllable production cost, suitable erase speed and retention characteristics.

### SUMMARY

In view of this, embodiments of the present disclosure provide a memory controller, a device, a system, an operating method thereof, and a storage medium.

According to a first aspect, an embodiment of the present disclosure provides a memory controller coupled to at least one memory device, wherein the memory device includes a plurality of word lines, each word line is coupled to a plurality of memory cells, and the plurality of memory cells form at least one physical page; the memory controller includes: a processor configured to: obtain a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

In some embodiments, the processor is further configured to: determine whether the read disturb state of the physical page is inferior according to a relationship between the statistical result and a preset threshold; and perform a data migration operation on the physical page based on the read disturb state of the physical page being determined to be inferior.

In some embodiments, the preset threshold includes a first threshold and/or a second threshold; and the processor is configured to: determine that the read disturb state of the physical page is inferior according to the first number being greater than the first threshold and/or according to the second number being greater than the second threshold.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the memory cell includes a plurality of memory bits, and the multi-bit storage data of the memory cell is read by multi-level read voltages; the processor is configured to: set a read mode to a single-level read mode before obtaining the statistical result of the physical page corresponding to the first read voltage; and the single-level read mode includes reading at least one bit of storage data stored in the memory cell through a first level read voltage.

In some embodiments, the processor is configured to: obtain the first read voltage and the preset threshold respectively.

In some embodiments, the processor is configured to: when the memory controller is powered on, obtain the first read voltage and the preset threshold from the memory device respectively, wherein the first read voltage and the preset threshold are both fixed values.

In some embodiments, the processor is configured to: when the memory controller is powered on, obtain an initial value of the first read voltage and an initial value of the preset threshold from the memory device respectively; and modify the initial value of the first read voltage and/or the initial value of the preset threshold by setting a feature command to obtain the first read voltage and the preset threshold.

In some embodiments, the memory controller further includes an interface coupled to the processor; the interface is configured to: receive the statistical result of the physical page corresponding to the first read voltage transmitted from the memory device; or the interface is configured to: receive read results of the physical page corresponding to the first read voltage and the second read voltage respectively or the read result of the physical page corresponding to the first read voltage transmitted from the memory device; and the processor is configured to: perform operations and counting on the read results to obtain a statistical result.

According to a second aspect, an embodiment of the present disclosure provides a memory system, including: one or more memory devices; and a memory controller according to an embodiment of the present disclosure, coupled to the memory device and configured to control the memory device.

In some embodiments, the memory controller is configured to: in a process of performing a read scrub on the memory device, send a first instruction, wherein the first instruction instructs to obtain a statistical result of a physical page; the memory device is configured to: in response to the first instruction, obtain the statistical result of the physical page, and send information including the statistical result of the physical page to the memory controller; and the memory controller is further configured to: determine whether a read disturb state of the physical page is inferior according to the statistical result and a preset threshold; and perform a data migration operation on the physical page according to the read disturb state of the physical page being inferior.

According to a third aspect, an embodiment of the present disclosure provides a memory device, including: a plurality of word lines, wherein each word line is coupled to a plurality of memory cells, and the plurality of memory cells form at least one physical page; a peripheral circuit coupled to the plurality of word lines and configured to: obtain a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

In some embodiments, the peripheral circuit is further configured to: determine whether the read disturb state of the physical page is inferior according to a relationship between the statistical result and a preset threshold; and perform a data migration operation on the physical page whose read disturb state is determined to be inferior.

In some embodiments, the preset threshold includes a first threshold and/or a second threshold; and the peripheral circuit is configured to: determine that the read disturb state of the physical page is inferior according to the first number being greater than the first threshold and/or according to the second number being greater than the second threshold.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the memory cell includes a plurality of memory bits, and the multi-bit storage data of the memory cell is read by multi-level read voltages; the peripheral circuit is configured to: set a read mode to a single-level read mode before obtaining the statistical result of the physical page corresponding to the first read voltage; and the single-level read mode includes reading at least one bit of storage data stored in the memory cell through a first level read voltage.

In some embodiments, the peripheral circuit is configured to: obtain the first read voltage and the preset threshold.

In some embodiments, the peripheral circuit is configured to: when the memory device is powered on, obtain the first read voltage and the preset threshold from the memory cell respectively, wherein the first read voltage and the preset threshold are both fixed values.

In some embodiments, the peripheral circuit is configured to: when the memory device is powered on, obtain an initial value of the first read voltage and an initial value of the preset threshold from the memory cell respectively; and modify the initial value of the first read voltage and/or the initial value of the preset threshold by setting a feature command to obtain the first read voltage and the preset threshold.

In some embodiments, the plurality of memory cells coupled to a word line form a plurality of physical pages; the plurality of physical pages includes a plurality of target physical pages; the peripheral circuit is configured to: apply the first read voltage to a selected word line of the plurality of word lines; for each target physical page of the plurality of target physical pages coupled to the selected word line, determine a read disturb state of the respective target physical page according to a statistical result corresponding to the respective target physical page corresponding to the first read voltage; and float the selected word line after completing the read disturb state of all target physical pages coupled to the selected word line.

In some embodiments, the statistical result includes a first number; the peripheral circuit is configured to: read the stored data of the physical page corresponding to the first read voltage to obtain a first result; adjust the first read voltage to obtain an adjusted read voltage, and read the stored data of the physical page under the adjusted read voltage to obtain a second result; perform a logical operation on the first result and the second result to obtain a third result; and count the number of bits in the third result that represent that the second result is flipped relative to the first result to obtain the first number.

In some embodiments, the peripheral circuit includes: a first latch configured to store the first result; a second latch configured to store the second result; and a third latch configured to store the third result.

According to a fourth aspect, an embodiment of the present disclosure provides a memory system, including: one or more memory devices according to an embodiment of the present disclosure; and a memory controller coupled to the memory device and configured to control the memory device.

In some embodiments, the memory controller is configured to: in a process of performing a read scrub on the memory device, send a second instruction, wherein the first instruction instructs to obtain a read disturb state of a physical page; the memory device is configured to: in response to the second instruction, obtain a statistical result of the physical page corresponding to the first read voltage, and determine whether the read disturb state of the physical page is inferior based on a relationship between the statistical result and the preset threshold; and send information including the read disturb state of the physical page to the memory controller; and the memory controller is further configured to: perform a data migration operation on the physical page according to the read disturb state of the physical page being inferior.

In some embodiments, the memory controller is configured to: in a process of performing read scrub on the memory device, send a third instruction, wherein the third instruction instructs to obtain a read disturb state of all target physical pages coupled to the word line; the memory device is configured to: in response to the third instruction, obtain a statistical result corresponding to each target physical page coupled to the word line corresponding to the first read voltage, and determine whether the read disturb state of each target physical page is inferior according to a relationship between the statistical result and the preset threshold; and send information including the read disturb state of all physical pages coupled to the word line to the memory controller; and the memory controller is further configured to: perform a data migration operation on all target physical pages coupled to the word line according to the read disturb state of all target physical pages coupled to the word line being inferior.

According to a fifth aspect, an embodiment of the present disclosure provides an operating method of a memory system, wherein the operating method of the memory system includes: a memory controller of the memory system, in a process of performing read scrub on a memory device of the memory system, obtaining a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

According to a sixth aspect, an embodiment of the present disclosure provides an operating method of a memory system, wherein the operating method of the memory system includes: a memory controller of the memory system, in a process of performing read scrub on a memory device of the memory system, the memory device obtains a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determines a read disturb state of the physical page according to the statistical result.

According to a seventh aspect, an embodiment of the present disclosure provides a computer-readable storage medium, wherein the computer-readable storage medium stores a computer program, and when the computer program is executed by a processor, the steps of the operating method of the embodiments of the present disclosure are implemented.

In the embodiments of the present disclosure, the read disturb state of the physical page is determined by obtaining the first number of bits flipped in two read results of the physical page under the specific first read voltage (the first read voltage is less than the second preset read voltage) and the read voltage whose voltage difference with the first read voltage is less than the preset voltage, and/or the second number of bits of the physical page not successfully read using the first read voltage, and comparing the obtained data with a preset threshold. In this implementation of the present disclosure, a direct comparison manner is simple, and a read disturb state of a physical page may be quickly determined without undergoing a complex decoding process such as a low-density parity-check (LDPC); and the obtained first number and/or second number are both statistical results, a storage space occupied by the statistical results is relatively small, and a large number of input/output (I/O) transmission are not required to obtain the statistical results, and a power consumption consumed in performing the determining process is relatively low.

### BRIEF DESCRIPTION OF DRAWINGS

In the drawings, like reference numbers refer to like or similar parts or elements throughout the several drawings unless otherwise specified. These drawings are not necessarily drawn to scale. It should be understood that these drawings depict only some implementations disclosed in accordance with the present disclosure and should not be considered as limiting the scope of the present disclosure.

FIG. 1 is a schematic diagram of an exemplary system with a memory system according to an embodiment of the present disclosure;

FIG. 2A is a schematic diagram of an exemplary memory card with a memory system according to an embodiment of the present disclosure;

FIG. 2B is a schematic diagram of an exemplary solid state drive with a memory system according to an embodiment of the present disclosure;

FIG. 3A is a schematic top view of a distribution of memory cells coupled to each word line according to an embodiment of the present disclosure;

FIG. 3B is a schematic diagram of an exemplary memory including a peripheral circuit according to an embodiment of the present application;

FIG. 4 is a schematic cross-sectional view of a memory cell array including a memory string according to an embodiment of the present disclosure;

FIG. 5 is a schematic diagram of an exemplary memory device including a memory cell array and a peripheral circuit according to an embodiment of the present application;

FIG. 6 is a schematic diagram of a read operation process of a memory system according to an embodiment of the present disclosure;

FIG. 7 is a schematic diagram of an exemplary composition structure with a memory system according to an embodiment of the present disclosure;

FIG. 8 is a schematic diagram of threshold voltage distribution corresponding to an exemplary each storage state in a TLC according to an embodiment of the present disclosure;

FIG. 9 is a schematic diagram of an exemplary read disturb state determination operation process of a memory controller according to an embodiment of the present disclosure;

FIG. 10 is a first schematic diagram of threshold voltage distribution corresponding to a read disturb problem occurring in an exemplary each storage state of a TLC according to an embodiment of the present disclosure;

FIG. 11 is a second schematic diagram of threshold voltage distribution corresponding to a read disturb problem occurring in an exemplary each storage state of a TLC according to an embodiment of the present disclosure;

FIG. 12 is a schematic diagram of an exemplary memory device including a plurality of word lines and a plurality of bit lines according to an embodiment of the present disclosure;

FIG. 13 is a schematic diagram of interaction between a memory controller and a memory device in a memory system according to an embodiment of the present disclosure;

FIG. 14 is a schematic flowchart of an exemplary read scrub operation related to read disturb according to an embodiment of the present disclosure;

FIG. 15 is a schematic flowchart of an exemplary testing read scrub process related to read disturb according to an embodiment of the present disclosure;

FIG. 16 is a first schematic flowchart of an implementation of an operating method of a memory system configured to execute according to an embodiment of the present disclosure;

FIG. 17 is a second schematic flowchart of an implementation of an operating method of a memory system configured to execute according to an embodiment of the present disclosure;

FIG. 18 is a schematic diagram of a composition structure of a storage medium according to an embodiment of the present disclosure.

### DETAILED DESCRIPTION

Exemplary implementations disclosed in the present disclosure will be described in more detail below with reference to the accompanying drawings. Although exemplary implementations of the present disclosure are shown in the accompanying drawings, it is to be understood that the present disclosure may be implemented in various forms and should not be limited to the implementations set forth herein. Rather, these embodiments are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that the present disclosure may be practiced without one or more of these details. In other examples, in order to avoid confusion with the present disclosure, some technical features known in the art are not described; that is, not all features of the actual embodiment are described here, and well-known functions and structures are not described in detail.

In addition, the drawings are merely schematic illustrations of the present disclosure, and are not necessarily drawn to scale. Like reference numerals in the drawings refer to the same or similar parts, and repeated description thereof will be omitted. Some of the memory block diagrams shown in the drawings are functional entities and do not necessarily have to correspond to physically or logically separate entities. These functional entities may be implemented in software form, or implemented in one or more hardware modules or integrated circuits, or implemented in different networks and/or processor devices and/or microcontroller devices.

The flowchart shown in the drawings is merely exemplary and not necessarily all steps. For example, some steps may be further decomposed, and some steps may be combined or partially combined, so the actual execution sequence may be changed according to actual conditions.

A term used herein is for the purpose of describing a particular embodiment only and is not to be considered as limitation of the present disclosure. As used herein, the singular forms “a”, “an” and “the” are intended to include the plural forms as well, unless the context clearly dictates otherwise. It should also be understood that the terms “consists of” and/or “comprising”, when used in this description, identify the presence of features, integers, steps, operations, elements and/or parts, but do not exclude the presence of one or more other features, integers, steps, operations, elements, parts and/or groups. As used herein, the term “and/or” includes any and all combinations of the associated listed items.

Memory devices in embodiments of the present disclosure include but are not limited to a three-dimensional NAND-type memory, and for case of understanding, a three-dimensional NAND-type memory is used as an example for illustration.

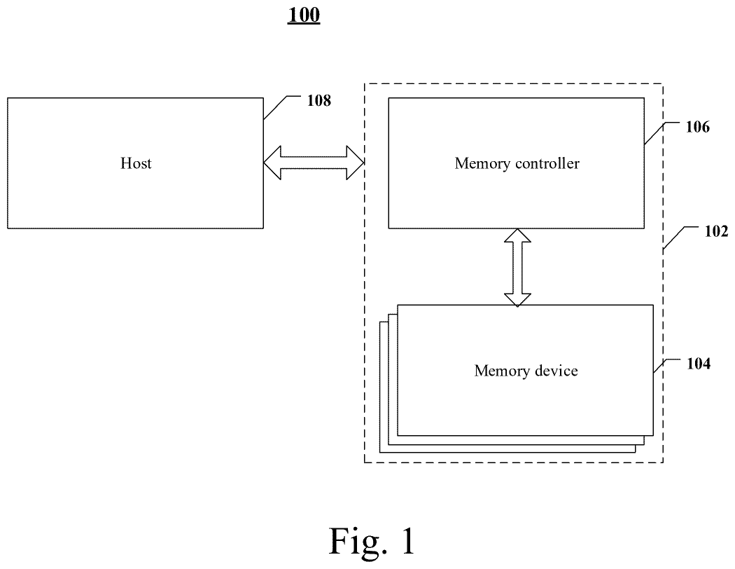

FIG. 1 illustrates a memory block diagram of an exemplary system 100 with memory controllers in accordance with some aspects of the present disclosure. The system 100 may be a mobile phone, a desktop computer, a laptop computer, a tablet, a vehicle computer, a gaming console, a printer, a positioning device, a wearable electronic device, a smart sensor, a Virtual Reality (VR) device, an Augment Reality (AR) device, or any other suitable electronic devices having memory therein. As shown in in FIG. 1, system 100 may include a host 108 and a memory system 102, and the memory system 102 has one or more memory devices 104 and a memory controller 106. The host 108 may be a processor of an electronic device (e.g., a Central Processing Unit (CPU)) or a System of Chip (SoC) (e.g., an Application Processor (AP)). Host 108 may be configured to send data to or receive data from memory device 104.

According to some implementations, memory controller 106 is coupled to memory device 104 and host 108 and is configured to control memory device 104. Memory controller 106 may manage data stored in memory device 104 and communicate with host 108. In some implementations, the memory controller 106 is designed to operate in low duty cycle environments, e.g., Secure Digital (SD) card, Compact Flash (CF) card, Universal Serial Bus (USB) flash drive, or other media for use in electronic devices such as personal computer, digital camera, mobile phone, etc.

In some implementations, the memory controller 106 is designed to operate in high duty cycle environment Solid State Drive (SSD) or Embedded Multi Media Card (cMMC), where SSD or eMMC is used as data memory for mobile devices such as smartphone, tablet computer, laptop computer, and enterprise storage array.

Memory controller 106 may be configured to control operations of memory device 104, e.g., read, erase and program operations. Memory controller 106 may also be configured to manage various functions related to data stored or to be stored in memory device 104, including but not limited to bad memory block management, garbage collection, logical-to-physical address translation, wear leveling, etc. In some implementations, memory controller 106 is also configured to process error correction code related to data read from or written to memory device 104.

The memory controller 106 may also perform any other suitable functions, e.g., formatting the memory device 104. Memory controller 106 may communicate with external devices (e.g., host 108) according to a particular communication protocol. For example, the memory controller 106 may communicate with external devices through at least one of various interface protocols, such as USB protocol, MMC protocol, Peripheral Component Interconnection (PCI) protocol, PCI Express (PCI-E) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

The memory controller 106 and one or more memory device 104 may be integrated into various types of storage devices, e.g., included in the same package (e.g., Universal Flash Storage (UFS) package or eMMC package). That is, memory system 102 may be implemented and packaged into different types of end electronic products.

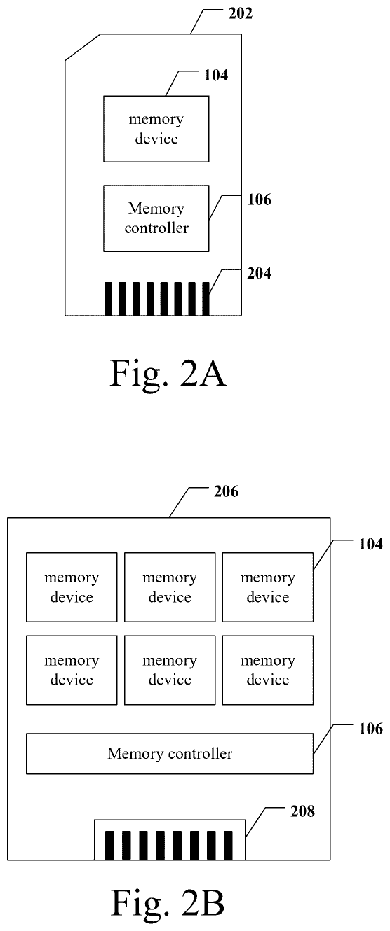

In one example as shown in FIG. 2A, memory controller 106 and a single memory device 104 may be integrated into a memory card 202. Memory card 202 may include a PC card (PCMCIA, personal computer memory card international association), a CF card, a smart media (SM) card, a memory stick, a mulinstant of timedia card (MMC, RS-MMC, MMCmicro), an SD card (SD, miniSD, microSD, SDHC), a UFS, etc. Memory card 202 may further include a memory card connector 24 coupling memory card 202 with a host (e.g., host 108 in FIG. 1).

In another example as shown in FIG. 2B, memory controller 106 and multiple memory devices 104 may be integrated into a SSD 206. The SSD 206 may further include an SSD connector 208 coupling the SSD 206 with a host (e.g., host 108 in FIG. 1). In some implementations, the storage capacity and/or operating speed of the SSD 206 is greater than the storage capacity and/or operating speed of memory card 202.

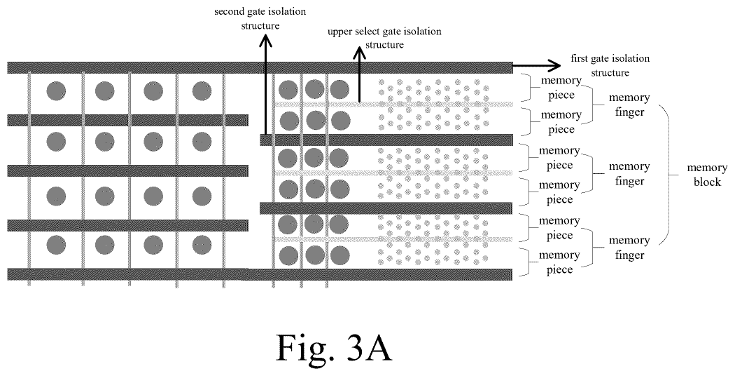

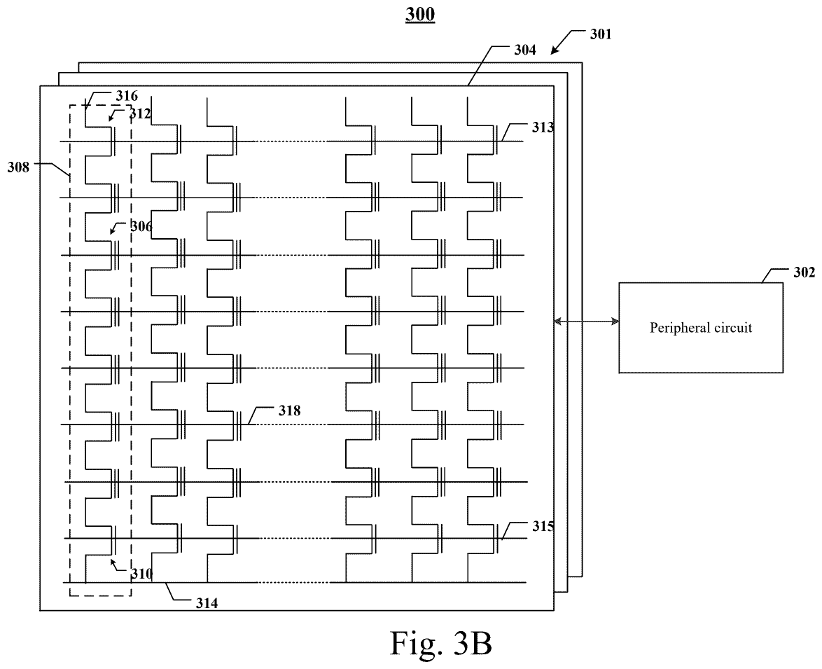

FIG. 3A for example shows a schematic structural diagram of a memory cell array of a three-dimensional NAND-type memory, as shown in FIG. 3A, a memory cell array of a three-dimensional NAND-type memory is composed of a plurality of rows of memory cell rows parallel to each other and parallel to a gate isolation structure, each two rows of memory cell rows are separated by the gate isolation structure and an upper select gate isolation structure, and each memory cell row includes a plurality of memory cells. The gate isolation structure may include a first gate isolation structure and a second gate isolation structure, the first gate isolation structure divides the memory cell array into a plurality of memory blocks, the plurality of second gate isolation structures may divide the memory block into a plurality of fingers, an upper select gate isolation structure disposed in the middle of each finger may divide the finger into two portions, thereby dividing the finger into two memory strings, and different memory strings may be selected or deselected by applying a select voltage or a deselect voltage on the corresponding top select gate (TSG). One memory block shown in FIG. 3A includes 6 memory strings, and in actual application, the number of memory strings in one memory block is not limited thereto.

In some embodiments, each memory block may be coupled to a plurality of word lines, a plurality of memory cells with each word line coupled to one memory string form one or more physical pages, wherein the number of physical pages is related to the number of memory bits contained in the memory cell. For example, all memory cells in each memory string in FIG. 3A (the number of memory bits are one bit) are coupled to form a physical page.

FIG. 3B illustrates a schematic circuit diagram of an exemplary memory device 300 including peripheral circuitry according to some aspects of the present disclosure. Memory device 300 may be an example of memory device 104 in FIG. 1. The memory device 300 may include a memory cell array 301 and a peripheral circuit 302 coupled to the memory cell array 301. Taking memory cell array 301 being a three-dimensional NAND-type memory cell array as an example for illustration, where memory cells 306 are NAND-type memory cells, and memory cells 306 are provided in the form of an array of memory strings 308, each memory string 308 extending vertically over a substrate (not shown). In some implementations, each memory string 308 includes multiple memory cells 306 coupled in series and stacked vertically. Each memory cell 306 may retain a continuous analog value, e.g., voltage or charge, depending on the number of electrons trapped within the region of the memory cell 306. Each memory cell 306 may be a “floating gate” type memory cell including a floating gate transistor, or a “charge trap” type memory cell including a charge trap transistor.

In some implementations, each memory cell 306 is a Single-level Cell (SLC) that has two possible storage states and may thus store one bit of data. For example, a first storage state of “0” may correspond to a first voltage range, and a second storage state of “1” may correspond to a second voltage range. In some implementations, each memory cell 306 is a Multi-Level Cell (MLC) capable of storing more than a single bit of data in more than four storage states. For example, an MLC may store two bits per cell (also known as a Double-Level Cell), three bits per cell (also known as a Trinary-Level Cell (TLC)), four bits per cell (also known as a Quad-Level Cell (QLC)), five bits per cell (also known as a Penta-level cell (PLC)), or more than five bits per cell. Each MLC can be programmed to assume a range of possible nominal storage values. In one example, if each MLC stores two bits of data, the MLC can be programmed to assume one of three possible program levels from the erased state through writing one of three possible nominal storage values into the cell, a fourth nominal storage value may be used for the erase state.

It is to be noted that the storage state mentioned here is also the storage state of the memory cell mentioned in the present disclosure. Different memory cells have different numbers of storage states. e.g., a SLC type memory cell has two storage states (i.e., two storage states), where the two storage states include a program state and an erase state. As another example, an MLC type memory cell has four storage states, where the four storage states include one erase state and three program states. As yet another example, a TLC type memory cell has eight storage states, where the eight storage states include one erase state and seven program states. In some implementation, the QLC type memory cell has sixteen storage states, where the sixteen storage states include one erase state and fifteen program states.

As shown in FIG. 3B, each memory string 308 may include a bottom select gate (BSG) 310 (also referred to as a source side select transistor) at its source end and a top select gate (TSG) 312 (also referred to as a drain side select transistor) at its drain end. BSG 310 and TSG 312 may be configured to activate the selected memory cell string 308 during read operation and program operation. In some implementations, the sources of memory strings 308 in a same memory block 304 are coupled through a same source line (SL) 314 (e.g., a common SL). In other words, according to some implementations, all memory strings 308 in a same memory block 304 have an array common source (ACS). According to some implementations, TSG 312 of each memory string 308 is coupled to a corresponding bit line (BL) 316 from which data may be read or written via an output bus (not shown). In some implementations, each memory string 308 is configured to be selected or deselected through applying a select voltage (e.g., above the threshold voltage of a transistor with a TSG 312) or a deselect voltage (e.g., 0V) to the corresponding TSG 312 via one or more TSG lines 313 and/or applying a select voltage (e.g., above the threshold voltage of a transistor with a BSG 310) or a deselect voltage (e.g., 0V) to the corresponding BSG 310 via one or more BSG lines 315.

As also shown in FIG. 3B, a memory string 308 may be organized into multiple memory blocks 304 each of which may have a common source line 314 (e.g., coupled to ground). In some implementations, each memory block 304 is the basic data unit for an erase operation, i.e., all memory cells 306 on the same memory block 304 are erased simultaneously. To erase the memory cell 306 in the selected memory block 304, the source line 314 coupled to the selected memory block 304 and to the unselected memory blocks 304 in the same plane as the selected memory block 304 may be biased with an erase voltage (Vers) (e.g., a high positive voltage (e.g., 20V or higher)). It is to be understood that, in some examples, erase operations may be performed at the half-memory block level, at the quarter-memory block level, or at a level with any suitable number of memory blocks or any suitable fraction of memory blocks. The memory cells 306 of adjacent memory strings 308 may be coupled through a word line 318 that selects which row of memory cells 306 is affected by read and program operations.

Referring to FIG. 3B, each memory cell 306 of the multiple memory cells is coupled to a corresponding word line 318, and each memory string 308 is coupled to a corresponding bit line 316 through a corresponding select transistor (e.g., top select transistor (TSG) 312).

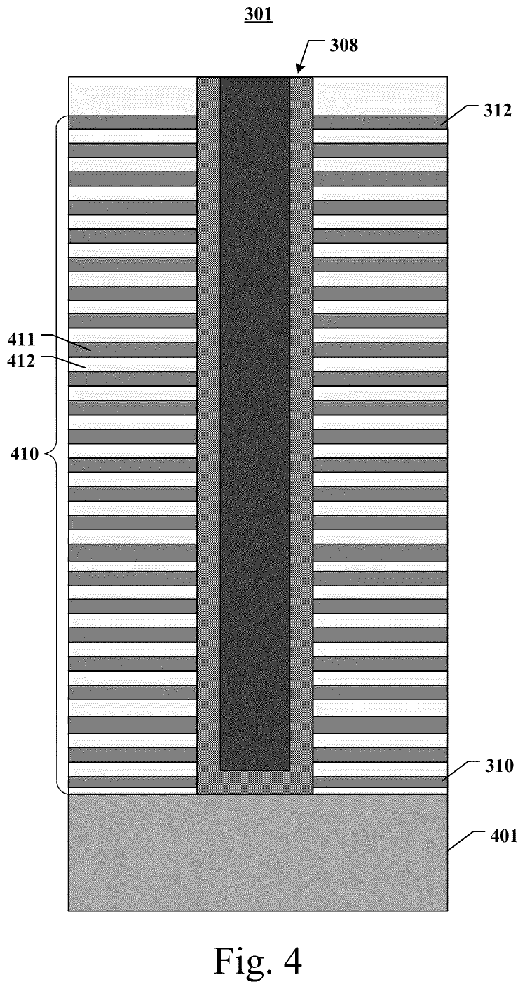

FIG. 4 illustrates a schematic cross-sectional view of an exemplary memory cell array 301 including memory strings 308, e.g., NAND, according to some aspects of the present disclosure. As shown in FIG. 4, the NAND memory cell array 301 may include a stacked structure 410, the stacked structure 410 includes multiple gate layers 411 and multiple insulating layers 412 alternately stacked in sequence, and the channel structure vertically penetrating through the gate layers 411 and the insulating layers 412, wherein the channel structure is coupled to each gate layer to form a memory cell, and the channel structure is coupled to multiple gate layers in the stacked structure 410 to form the memory string 308. Gate layers 411 and the insulating layers 412 may be stacked alternately, and two adjacent gate layers 411 are separated by an insulating layer 412.

A constituent material of the gate layer 411 may include a conductive material. Conductive materials include, but are not limited to, tungsten (W), cobalt (Co), copper (Cu), aluminum (Al), polysilicon, doped silicon, silicide, or any combination thereof. In some embodiments, each gate layer 411 includes a metal layer, e.g., a tungsten layer. In some embodiments, each gate layer 411 includes a doped polysilicon layer. Each gate layer 411 may include a control gate surrounding a memory cell. A gate layer 411 at the top of a stacked structure 410 may extend laterally as a top select gate line, a gate layer 411 at the bottom of a stacked structure 410 may extend laterally as a bottom select gate line, and a gate layer 411 extending laterally between a top select gate line and a bottom select gate line may serve as a word line layer.

In some embodiments, a stacked structure 410 may be disposed on a substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other appropriate material.

In some embodiments, a memory string 308 includes a channel structure extending vertically through stacked structure 410. In some implementations, a channel structure includes a channel hole filled with semiconductor material(s) (e.g., as a semiconductor channel) and dielectric material(s) (e.g., as a memory film). In some implementations, a semiconductor channel includes silicon, e.g., polysilicon. In some implementations, a memory film is a composite dielectric layer including a tunneling layer, a storage layer (also referred to as a “charge trapping/storage layer”), and a memory blocking layer. A channel structure may have a cylindrical shape (e.g., a pillar shape). According to some implementations, a semiconductor channel, a tunneling layer, a storage layer and a memory blocking layer are radially arranged in this order from the center of the pillar toward the outer surface of the pillar. A tunneling layer may include silicon oxide, silicon oxynitride, or any combination thereof. A storage layer may include silicon nitride, silicon oxynitride, or any combination thereof. A memory blocking layer may include silicon oxide, silicon oxynitride, a high-k (high-k) dielectric, or any combination thereof. In an example, a memory film may include a composite layer of silicon oxide/silicon oxynitride/silicon oxide (ONO).

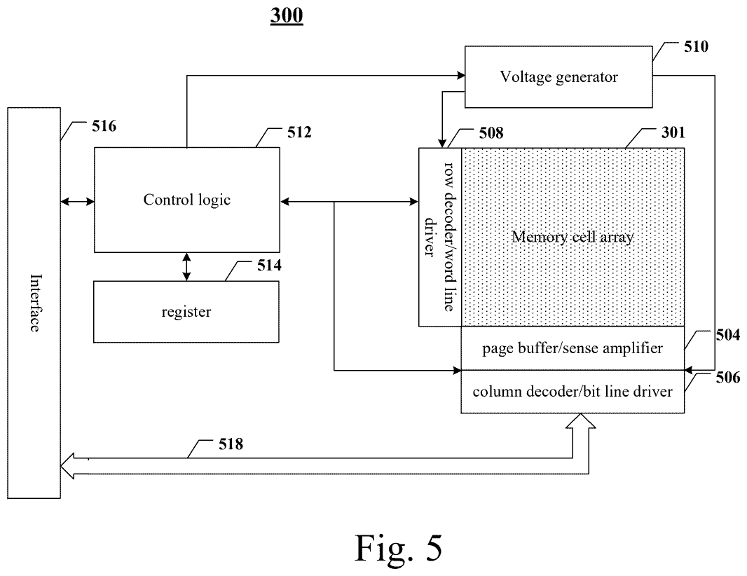

Referring back to FIG. 3B, the peripheral circuit 302 may be coupled to the memory cell array 301 through bit line 316, word line 318, source line 314, BSG line 315, and TSG line 313. The peripheral circuit 302 may include any suitable analog, digital, and mixed-signal circuitry for facilitating operation of the memory cell array 301 through applying a voltage signal and/or a current signal to and sensing voltage signal and/or current signal from each target memory cell 306 via bit line 316, word line 318, source line 314, BSG line 315, and TSG line 313. The peripheral circuit 302 may include various types of peripheral circuits formed with metal-oxide-semiconductor (MOS) technology. For example, FIG. 5 illustrates some exemplary peripheral circuits, the peripheral circuit includes page buffer/sense amplifier 504, column decoder/bit line driver 506, row decoder/word line driver 508, voltage generator 510, control logic 512, register 514, interface 516 and data bus 518. It is to be understood that in some examples, additional peripheral circuits not shown in FIG. 5 may also be included.

The page buffer/sense amplifier 504 may be configured to read data from and program (write) data to the memory cell array 301 according to control signals from the control logic 512. In one example, the page buffer/sense amplifier 504 may store program data (written data) to be programmed into the memory cell array 301. In another example, the page buffer/sense amplifier 504 may perform a program verify operation to ensure that data has been correctly programmed into memory cell 306 coupled to selected word line 318. In yet another example, the page buffer/sense amplifier 504 may also sense a low power signal from bit line 316 representing a data bit stored in memory cell 306 and amplify a small voltage swing to a recognizable logic level during a read operation. The column decoder/bit line driver 506 may be configured to be controlled by control logic 512 and to select one or more memory strings 308 through applying a bit line voltage obtained from voltage generator 510.

The row decoder/word line driver 508 may be configured to be controlled by control logic 512 and to select/deselect memory block 304 of memory cell array 301 and to select/deselect word line 318 of memory block 304. The row decoder/word line driver 508 may also be configured to drive word line 318 with a word line voltage obtained from voltage generator 510. In some implementations, the row decoder/word line driver 508 may also select/deselect and drive the BSG line 315 and the TSG line 313. As described in detail below, the row decoder/word line driver 508 is configured to perform program operations on the memory cells 306 coupled to the selected word line 318. The voltage generator 510 may be configured to be controlled by the control logic 512, and obtain word line voltage (e.g., read voltage, program voltage, pass voltage, channel boost voltage, verify voltage, etc.), bit line voltage and source line voltage to be supplied to the memory cell array 301.

The control logic 512 may be coupled to each of other units of the peripheral circuit described above, and configured to control operations of each of the other units of the peripheral circuit. The register 514 may be coupled to the control logic 512 and include status register, command register and address register for storing status information, command operation code (OP code) and command address for controlling operations of each of the peripheral circuits. The interface 516 may be coupled to control logic 512 and act as a control buffer to buffer and relay control commands received from a host (not shown) to control logic 512 and to buffer and relay status information received from the control logic 512 to the host. Interface 516 may also be coupled to column decoder/bit line driver 506 via data bus 518 and act as a data I/O interface and data buffer to buffer and relay data to/from memory cell array 301.

Data is stored in the floating gate transistor in the memory device, and the floating gate is surrounded by the insulator.

The principle of the data retention issue is: electrons stored in the floating gate will “escape” through the insulating layer under the effect of the intrinsic electric field over time, especially as the insulating effect of the insulator becomes gradually deteriorated (the number of erasing times increases), and the “escape” of electrons becomes increasingly easy. When the number of the “escape” of electrons reaches a certain amount, a bit “0” is flipped to a bit “1”, and when the number of bit flipped exceeds the error correction capability, the situation that the user data is lost will occur.

The principle of the read disturb issue is: when reading data, in order to ensure that other floating gate transistors are turned on, it is necessary to apply a turn-on voltage on other unselected word lines, which causes these transistors to suffer from slight “programming”, and as the number of reads increases, more and more electrons enter the floating gate transistor, which may eventually cause bit flipping (flipped from 1 to 0). When the number of bits flipped exceeds the error correction capability, the situation that the user data is lost will occur.

Although data retention issue and read disturb issue both result in bit flipping of data stored in the memory device, the directions of the bit flipping resulting from both issues are opposite: read disturb injects additional electrons, resulting in a bit flipping from “1” to “0”; while data retention is a loss of electrons, resulting in a bit flipping from “0” to “1”. In some embodiments, from the threshold voltage profile, read disturb causes the threshold voltage distribution to at least partially shift right, while data retention causes the threshold voltage distribution to at least partially shift left.

When the threshold voltage is shifted left or right too much, when the original read voltage is used to read the data of the memory cell, the possibility that the read error occurs is very large, and at this time, the error correction code is used for error correction. The error correction code in the embodiments of the present disclosure includes, but is not limited to, a low-density parity-check (LDPC), and the following uses LDPC as an example only for description.

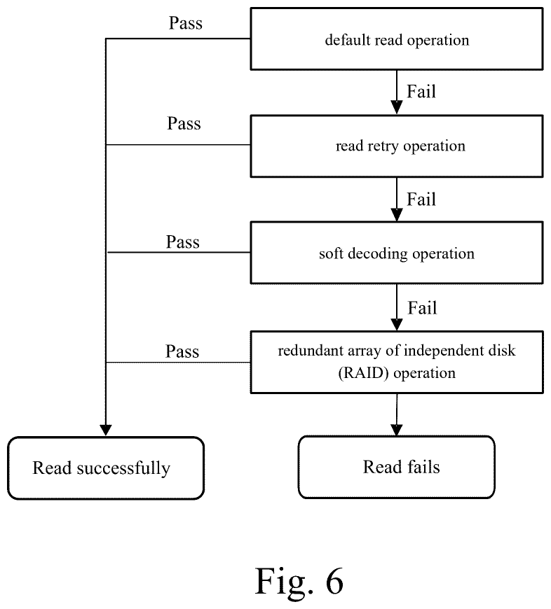

FIG. 6 shows a schematic diagram of an exemplary read operation flow of a memory system. As shown in FIG. 6, when the memory controller controls the memory device to perform a read operation, a default read operation is firstly performed on the memory cell of the corresponding physical address, a read retry operation is performed after the default read operation fails, a soft decoding operation (or referred to as soft decision decoding) is performed after the read retry operation fails, a redundant array of independent disk (RAID) operation is performed after the soft decoding fails, the read operation is stopped after the RAID operation fails, and the read fails due to the failure of error correction, and the memory controller sends a read fail signal to the host 108.

In some embodiments, a read retry operation may usually be performed by querying a retry table provided by the manufacturer. The essence of the read retry operation is an error correction mechanism, in which a read offset voltage corresponding to different situations (such as data retention, read disturb, etc.) is stored in the retry table to provide a reference voltage for reading data, each memory cell is read again by querying the read voltage whose retry table tries to deviate from the normal threshold voltage, and error correction is performed by using the error correction algorithm, in an attempt to correctly read the data.

The data in the memory device needs to avoid an uncorrectable error correction code (UECC) or a data error recovery failure caused by read disturb, and needs to perform read scrub (or referred to as background data scrub, generally performed when the memory system is idle). However, since the number of physical pages included in the memory device is relatively large, it is difficult to perform read scrub on all physical pages, and only read scrub sampling can be performed. With the rise of flash memory products such as QLC and PLC, the duration of the read operation becomes longer and longer, which leads to increasingly large read scrub costs. How to quickly realize the identification of read disturb has a certain difficulty. In addition, when performing data scanning with respect to read disturb, the level corresponding to the read disturb in the retry table is generally mainly used, and if a data retention issue occurs in one piece of data but no read disturb issue occurs, the current read scrub shows that the read retry operation fails, so that the garbage collection (GC) operation is triggered by mistake. Here, garbage collection is to read and rewrite valid data on one or several memory blocks onto other memory blocks.

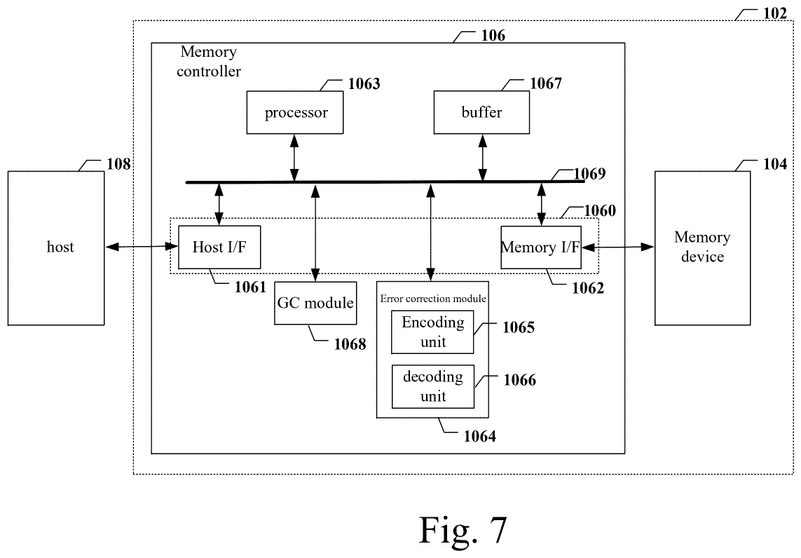

Based on one or more of the foregoing problems, according to a first aspect, an embodiment of the present disclosure provides a memory controller, as shown in FIG. 7, the memory controller 106 is coupled to the at least one memory device 104, the memory device 104 includes a plurality of word lines, each word line is coupled to a plurality of memory cells, and the plurality of memory cells form at least one physical page; the memory controller 106 includes an interface 1060; and the processor 1063 coupled to the interface 1060 and configured to: obtain a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

FIG. 7 is schematic diagram of a composition structure of a memory system of a memory controller. As shown in FIG. 7, the memory controller 106 is coupled to the memory device 104, and is configured to control the memory device 104 to perform operations such as read/write erase. The memory controller 106 may include a processor 1063 for controlling the memory controller 106 and the memory device 104 as a whole. In some embodiments, the processor 1063 may include one or more units having a logical operation capability, for example, a single-core or multi-core central processing unit (CPU) and/or a microcontroller unit (MCU).

In some embodiments, the memory controller 106 may further include an interface 1060 for data interaction with external devices. In some embodiments, the interface 1060 may include a host interface (I/F) 1061 and a memory interface (I/F) 1062, wherein the host interface 1061 is a connection interface between the host 108 and the memory controller 106, and the host interface 1061 allows the host and the memory controller to communicate according to a particular protocol, send read and write requests, and perform other operations. The memory interface 1062 is a connection interface between the memory controller 106 and the memory device 104, and the memory interface 1062 is configured to implement data transmission between the memory controller 106 and the memory device 104.

In some embodiments, the memory controller 106 may further include an error correction module 1064, a buffer 1067, garbage collection (GC) module 1068, and a bus 1069, etc. The error correction module 1064 may further include an encoding unit 1065 and a decoding unit 1066; the encoding unit 1065 is configured to encode the data to be stored to obtain check data, and the decoding unit 1066 is configured to decode the check data to detect and correct possible error data in a data transmission process. The buffer 1067 is configured to cache data. In some embodiments, the buffer 1067 may be a volatile memory device which has a relatively fast read/write speed, such as a Static Random Access Memory (SRAM) and/or a Dynamic Random Access Memory (DRAM). The garbage collection module 1068 is configured to read out valid data on some memory blocks after the storage space of the memory device reaches a certain threshold, rewrite and then mark the memory blocks to obtain a new backup memory block.

In some embodiments, the memory controller 106 may further include other modules not listed, such as a wear leveling module, a bad memory block management module, an SLC caching module, and the like.

In some embodiments, the memory device may include a NAND-type memory. For a structure of the memory device, refer to FIG. 3B, and details are not described herein again.

In some embodiments, the memory device includes a plurality of memory blocks, each memory block may be coupled to a plurality of word lines, each word line may be divided into a plurality of memory strings shown in FIG. 3A by the foregoing gate isolation structure (the first gate isolation structure or the second gate isolation structure) and the upper select gate isolation structure, different memory strings may be selected or deselected by applying a selection voltage or a deselect voltage on the corresponding top select gate TSG, each word line forms one or more physical pages with a plurality of memory cells coupled to one memory string, and a number of physical pages is the same as a number of memory bits included in the memory cell. For example, the memory cell is an SLC, and each word line forms a physical page with a plurality of memory cells coupled to one memory string; the memory cell is an MLC, and each word line forms two physical pages with a plurality of memory cells coupled to one memory string; the memory cell is a TLC, and each word line forms three physical pages with a plurality of memory cells coupled to one memory string, namely a lower page LP, a middle page MP and an upper page UP; and the memory cell is QLC, and each word line forms four physical pages with a plurality of memory cells coupled to one memory string.

In some embodiments, the memory device includes a plurality of memory blocks, each memory block may be coupled to a plurality of word lines, and all memory cells coupled to each word line form one or more physical pages, where the number of physical pages is the same as the number of memory bits included in the memory cell. For example, the memory cell is an SLC, and a plurality of memory cells coupled to each word line form a physical page; and the memory cell is a TLC, and a plurality of memory cells coupled to each word line form three physical pages. It should be noted that, in this embodiment, the division of the forgoing finger and the memory string is not performed similarly, but the top selection gate TSG corresponding to each word line is connected together.

In the embodiment of the present disclosure, the processor 1063 provides data support of whether performing data migration on the physical page by obtaining a statistical result of the physical page corresponding to the first read voltage, and determining the read disturb state of the physical page according to the statistical result.

Here, the read disturb state may be understood as a degree of progress of read disturb of data stored in a physical page, and the degree of progress may be divided into two or more levels. In some embodiments, the degree of progress may be divided into two levels, namely inferior and non-inferior.

In some embodiments, the processor 1063 is further configured to: determine whether the read disturb state of the physical page is inferior according to a relationship between a statistical result and a preset threshold; and perform a data migration operation on the physical page based on the read disturb state of the physical page being determined to be inferior.

Here, in combination with the rule of read disturb, the degree of progress of read disturb may be classified according to the situation of electron injection, and the data read disturb may include “inferior” or referred to as a first read disturb state and a “non-inferior” or referred to as a second read disturb state, and an amount of stored electron injection corresponding to the second read disturb state (non-inferior) is less than an amount of stored electron injection corresponding to the first read disturb state. That is, the amount of electron injection corresponding to the first read disturb state (inferior) is more severe. In some embodiments, when the read disturb state of the physical page is the first read disturb state (inferior), the data migration operation is performed on the data stored in the physical page.

In some embodiments, the processor 1063 is further configured to: not perform the data migration operation on the physical page based on the read disturb state of the physical page being non-inferior, that is, not perform a further operation on the memory cell where the physical page is located in this read scrub due to the data becoming to be inferior caused by read disturb.

In some embodiments, the processor 1063 is configured to: determine a read disturb state of the physical page according to an relation between a statistical result and a preset threshold, where the read disturb state determined herein may also be a degree of progress of read disturb of data stored in the physical page, and the degree of progress may be classified into a plurality of levels, for example, the foregoing “inferior” and “non-inferior” may correspond to two levels, or may have more other intermediate levels, and subsequent operations corresponding to different one or more levels may be different, for example, another intermediate level between “inferior” and “non-inferior” may be created, and then for a physical page determined to be the intermediate level, the physical page may be marked as a remarkable read scrub object, and verification is preferentially performed in subsequent read scrub.

It should be noted that, for a case where a memory string is divided, a minimum processing object of read disturb determination involved in this embodiment of the present disclosure may be data stored in a plurality of memory units coupled to one word line and one memory string; and for a case where memory string is not divided, a minimum processing object of read disturb determination in this embodiment of the present disclosure may be data stored in all memory units coupled to one word line.

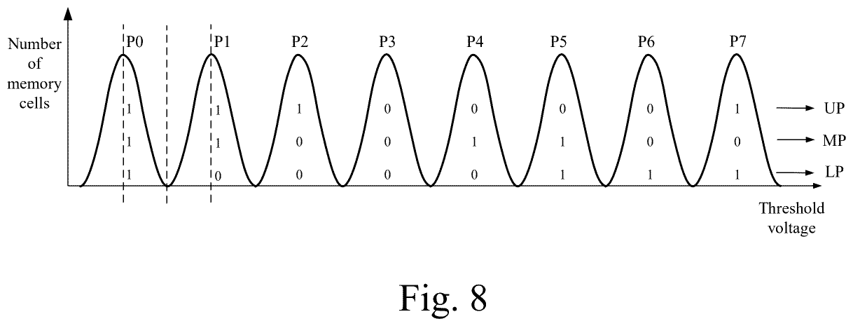

Taking the case where the memory string is divided as an example, for an SLC, a plurality of memory cells coupled to one memory string and one word line correspond to one physical page, and at this time, a statistical result of the physical page corresponding to the first read voltage is a statistical result corresponding to the corresponding physical page corresponding to the first read voltage; for TLC, a plurality of memory cells coupled to one memory string and one word line correspond to three physical pages, and at this time, a statistical result of the physical page corresponding to the first read voltage is obtained as a statistical result corresponding to a target physical page (a physical page corresponding to a memory bit used for differentiating the first and second storage states, the lower page as shown in FIG. 8) in the three physical pages at the first read voltage. It should be noted that the target physical page herein is related to a set voltage value of the first read voltage, and is not a certain fixed physical page.

In other words, in this embodiment of the present disclosure, obtaining a statistical result of the physical page corresponding to the first read voltage may be obtaining a statistical result of the target physical page in the at least one physical page corresponding to the word line corresponding to the first read voltage. For an SLC where a memory string is not divided, a physical page corresponding to a word line is a target physical page; and for a storage ternary where a memory string is divided and the memory bits are a plurality of bits, a number of physical pages corresponding to a word line is a product of a number of memory strings with a number of memory bits, and the word line corresponds to the same number of target physical pages as the number of memory strings.

As mentioned previously, from the threshold voltage distribution profile, it can be seen that the read disturb causes the threshold voltage distribution to shift at least partially to the right. In some implementations, the read disturb shifts the portion of the threshold voltage distribution that is in the lower storage state to the right, while the portion of the threshold voltage distribution that is in the higher storage state is shifted to the right not obviously, or even not shifted to the right. In some implementations, the read disturb shifts all storage states of the threshold voltage distribution to the right to some extent. It can be understood that, since the number of electrons corresponding to the lower storage state is smaller, when the injection amount is constant, the change caused to the storage state corresponding to the smaller number of electrons by the injection amount is more obvious, that is, it is more obvious for the phenomenon of the lower storage state threshold voltage distribution shifted to the right. Based on this, in this embodiment of the present disclosure, when determining the state of the read disturb, the statistical result of the voltage value less than the mean value of the threshold voltage range corresponding to the intermediate storage state of the physical page corresponding to the first read voltage is obtained.

In some embodiments, the number of memory bits included in the memory cell may be N bits (N is a positive integer greater than 1), the N memory bits correspond to 2^{N} storage states, and the mean value of the threshold voltage intervals corresponding to the intermediate storage state of the physical page may be the median value of the threshold voltage interval corresponding to a certain storage state of the middle position in the 2^{N}−1 level of read voltages. For example, using TLC as an example, the memory cell includes the number of memory bits of 3, and the 3 memory bits correspond to 8 storage states (in ascending order of threshold voltage distributions are the zeroth state P0, the first state P1, . . . , the seventh state P7).

Here, the first read voltage is less than the mean value of the threshold voltage interval corresponding to the intermediate storage state of the physical page, that is, the first read voltage is in the threshold interval corresponding to the lower storage state. In some embodiments, the first read voltage is less than a mean value of a total threshold voltage interval corresponding to a plurality of storage states where the memory cells coupled to the word line can be programmed into.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

Here, the plurality of storage states of the physical page may be understood as a plurality of storage states that the storage unit can be programmed. Taking TLC as an example, as shown in FIG. 8, the plurality of storage states of the physical page are P0 to P7, the first storage state and the second storage state may be respectively understood as the P0 state and the P1 state, the first threshold voltage may be understood as the median of voltage in the threshold voltage interval of the P0 state, that is, the threshold voltage corresponding to the dotted line in the P0 state in FIG. 8, and the second threshold voltage may be understood as the median of voltage in the threshold voltage interval of the P1 state, that is, the threshold voltage corresponding to the dotted line in the P1 state in FIG. 8. The first read voltage needs to be at a dotted line corresponding to the median of the threshold voltage of the P0 state and a dotted line corresponding to the median of the threshold voltage of the P1 state. In some embodiments, the first read voltage may be at a boundary between P0 and P1; or there is a voltage interval between P0 and P1, and the first read voltage may be in the voltage interval. For example, the first read voltage may be a median of the median of the threshold voltage of P0 state and the median of the threshold voltage of P1 state.

It should be noted that the storage states involved in describing the first read voltage and the second read voltage are both storage states corresponding to the time when data is written. The first storage state and the second storage state are also the lowest two storage states corresponding to the write data and not the lowest two storage states corresponding to the read disturb.

Here, the statistical result corresponding to the first read voltage may include a first number of bits flipped in two read results of the physical page corresponding to the first read voltage and a read voltage whose voltage difference with the first read voltage is less than a preset voltage, and/or a second number of bits of the physical page not successfully read using the first read voltage.

In some embodiments, the statistical result corresponding to the first read voltage may include a first number of bits flipped in two read results of the physical page corresponding to the first read voltage and a read voltage whose voltage difference with the first read voltage is less than a preset voltage.

Here, the read voltage whose voltage difference with the first read voltage is less than the preset voltage may be understood as the voltage near the first read voltage. It should be noted that the voltage near the first read voltage may be a voltage greater than the first read voltage, or may be a voltage less than the first read voltage. The difference between the two read voltage is less than a preset voltage. In some embodiments, the preset voltage ranges from 6 mV to 22 mV, for example, the preset voltage may be 6 mV, 11 mV, 16 mV, 22 mV.

In some embodiments, the memory controller further includes an interface coupled to the processor; the interface is configured to: receive the statistical result of the physical page corresponding to the first read voltage transmitted from the memory device; or the interface is configured to: receive, from the memory device, read results of the physical page corresponding to the first read voltage and the second read voltage respectively or the read result of the physical page corresponding to the first read voltage; and the processor is configured to: perform operations and statistics on the read results to obtain a statistical result.

In some embodiments, a read result corresponding to the first read voltage and a voltage near the first read voltage may be separately obtained, an XOR operation is performed on the two read results, and a first number is obtained by counting a value of “1” in the result of the XOR operation. The memory device is used as an execution body to complete a read operation corresponding to the first read voltage and the voltage near the first read voltage to obtain a read result; and the memory device or the memory controller is used as an execution body to complete XOR operation and counting. In the subsequent embodiments, the method of obtaining the first number through the internal hardware by the memory device will be further described.

In some embodiments, the statistical result corresponding to the first read voltage may include a second number of bits of the physical page not successfully read using the first read voltage.

Here, the bit not successfully read using the first read voltage may be understood as the bit in the physical page with the threshold voltage less than the first read voltage when the first read voltage is applied to the word line coupled to the physical page. In some embodiments, if the display value of bit with the threshold voltage less than the first read voltage may be “1”, the number of “1” read corresponding to the first read voltage may be counted to obtain the second number. The memory device is used as an execution body to complete the read operation of the first read voltage to obtain the read result; and the memory device or the memory controller is used as an execution body to complete the count of “1”.

It can be understood that, compared with sending the read result directly to the memory controller, by using the memory device as the executing body to complete the XOR operation and the count of “1”, that is, directly obtaining the first number and the second number by the memory device, the amount of transmitted data can be reduced, and the transmission time between the memory device and the memory controller can be saved.

In some embodiments, when the first number and the second number are obtained, a read mode of the memory device needs to be set to a single level read (SLC) mode. Here, in a single level read mode, a read operation reads a bit of storage data in a physical page. For example, when the lower page UP is read, whether the bit storage data corresponding to the lower page is 0 or 1 is read by using the first level read voltage between P0 and P1.

In some embodiments, the memory cell includes a plurality of memory bits, and the multi-bit storage data of the memory cell is read by multi-level read voltages; the processor is configured to: set a read mode to a single level read mode before obtaining the statistical result of the physical page corresponding to the first read voltage; and the single level read mode includes reading at least one bit of storage data stored in the memory cell through a first level read voltage.

Here, both the first read voltage and the voltage near the first read voltage may be understood as a first level read voltage, and for a memory cell with a multi-bit number of memory bits, when reading corresponding to the first read voltage and the voltage near the first read voltage, in a single level read mode, data in one memory bit in a corresponding physical page is obtained.

In some embodiments, the statistical result corresponding to the first read voltage may include a first number of bits flipped in two read results of the physical page corresponding to the first read voltage and a read voltage whose voltage difference with the first read voltage is less than a preset voltage, and a second number of bits of the physical page not successfully read using the first read voltage.

Here, the first number and the second number and the way of obtaining thereof may be understood with reference to the way of explaining and obtaining the foregoing first number and the second number.

When the obtained statistical result is different, the preset threshold corresponding to the obtained statistical result is also different. When the obtained statistical result is the first number, the preset threshold corresponding to the obtained statistical result for comparison is the first threshold; and when the obtained statistical result is the second number, the preset threshold corresponding to the obtained statistical result for comparison is the second threshold.

Both the first threshold and the second threshold may be adjusted according to actual conditions, and both the first threshold and the second threshold may vary within a certain range. It can be understood that the first threshold and the second threshold are set relatively strict, so that the corresponding data migration is performed on the data stored in the memory device when the read disturb state is not too bad; the first threshold and the second threshold are set relatively relax, so that the data migration triggered the read disturb at the root low frequency is performed on the data stored in the memory device.

In some embodiments, the first threshold may be a number of bits flipped in two read results under a read voltage corresponding to a critical point at which the read disturb triggered soft decoding operation and a voltage near the read voltage and a value near the number. In some embodiments, the first threshold includes a number of bits flipped in two read results at a second read voltage corresponding to read disturb triggered soft decoding enabled and a read voltage whose voltage difference with the second read voltage is less than a preset voltage.

Here, the read disturb shifts the threshold voltage to the right. In some embodiments, when the fail bit rate count of the read result reaches a preset count (for example, 400), it is considered that the hard decoding has failed to complete error correction, and soft decoding needs to be enabled, that is, the critical point for triggering soft decoding is reached, and at this time, the voltage shifted to the right when triggered soft decoding enabled occurs is derived; then the default read voltage and the voltage shifted to the right are used to obtain the read voltage corresponding to read disturb triggered soft decoding operation enabled, and the read voltage at this time is the second read voltage; and then the read results under the second read voltage and the voltage near the second read voltage are obtained, the XOR operation is performed on the two read results, and the first threshold is obtained by counting the value of “1” in the result of the XOR operation.

In some embodiments, the preset voltage ranges from 6 mV to 22 mV, for example, the preset voltage may be 6 mV, 11 mV, 16 mV, 22 mV.

In some embodiments, the second threshold may be a sum of the number of bits of the corresponding read voltage and a value near the sum when the threshold voltage is less than the critical point at which the read disturb triggered soft decoding operation starts. In some embodiments, the second threshold includes a number of bits read unsuccessfully under the second read voltage corresponding to the read disturb triggered soft decoding enabled.

Here, the number of bits read unsuccessfully under the second read voltage is the sum of the number of bits with the threshold voltage less than the second read voltage. In some embodiments, the second read voltage may also be obtained in the manner described above; then, the sum of the number of bits with the threshold voltage less than the second read voltage is obtained.

The way of obtaining the first number and the second number and the principle of setting the first read voltage, the first threshold and the second threshold included in the preset threshold have been described above. In some embodiments, the processor 1063 is configured to obtain the first read voltage and the preset threshold respectively. Here, the first read voltage and the preset threshold may be fixed values; or may be a value adjusted according to actual conditions of the memory device. The first read voltage and the preset threshold may be obtained once when the memory controller is powered on, or may be obtained as needed each time the trigger command is received. Various situations of the above first read voltage and the preset threshold may be arbitrarily combined without conflict.

In some embodiments, the processor 1063 is configured to: when the memory controller is powered on, obtain a first read voltage and a preset threshold from the memory device respectively; the first read voltage and the preset threshold are both fixed values.

Here, the first read voltage and the preset threshold are stored in the memory device according to the foregoing setting principle, so that when the memory controller is powered on, the first read voltage and the preset threshold are loaded into the buffer 1067 of the memory controller.

In some embodiments, the processor 1063 is configured to: when the memory controller is powered on, obtain an initial value of the first read voltage and an initial value of the preset threshold from the memory device respectively; and modify the initial value of the first read voltage and/or the initial value of the preset threshold by setting the feature command to obtain the first read voltage and the preset threshold.

Here, the feature command may set directly the memory device, the initial value of the first read voltage and the initial value of the preset threshold are stored in the memory device, or may be referred to as a default value, and the initial value of the first read voltage and/or the initial value of the preset threshold can be adjusted by setting the feature command if needed to be adjusted subsequently.

The following describes in detail how to use the relationship between the first number and/or the second number included in the statistical result and the first threshold and/or the second threshold included in the preset threshold to determine the read disturb state.

In some embodiments, the preset threshold includes a first threshold and/or a second threshold; and the processor is configured to: determine that the read disturb state of the physical page is inferior (the first read disturb state) according to the first number being greater than the first threshold and/or according to the second number being greater than the second threshold.

In some embodiments, the processor is further configured to: determine that the read disturb state of the physical page is non-inferior (the second read disturb state) according to the first number being less than or equal to the first threshold or according to the second number being less than or equal to the second threshold.

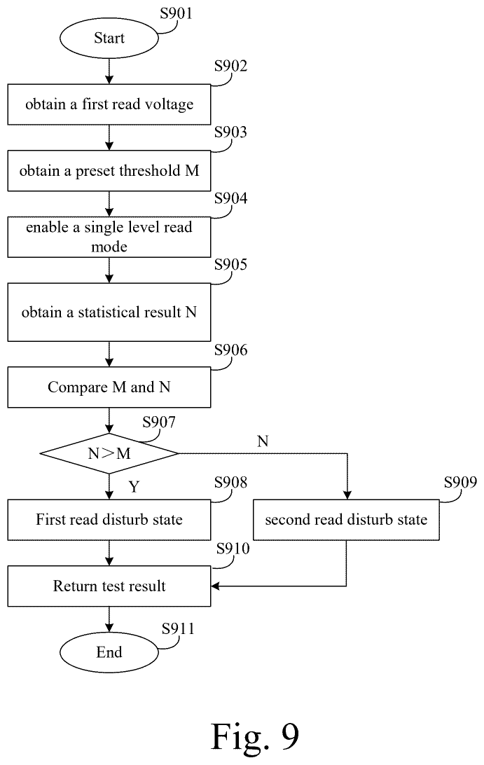

FIG. 9 shows a schematic diagram of an exemplary read disturb state determination operation flow of a memory controller. For example, as shown in FIG. 9, in a process of performing read scrub on the memory device by the memory controller, especially in a process of performing data scanning with respect to the read disturb issue, the processor 1063 of the memory controller may perform steps S901 to S911.
Step S901: Start the read disturb state determination procedure.

Next, step S902 is performed to obtain a first read voltage. Here, the principle of setting the first read voltage and the way of obtaining the first read voltage may be understood with reference to the foregoing description.

Next, step S903 is performed to obtain a preset threshold M. Here, the obtained preset threshold M may include a first threshold M1 and/or a second threshold M2. The principle of setting the preset threshold and the way of obtaining the preset threshold may be specifically understood with reference to the foregoing description.

Here, both the first read voltage and the preset threshold may be obtained from the buffer 1067 of the memory controller. It should be noted that step S902 and step S903 may also be that step S903 is performed before step S902; or step S902 and step S903 may be performed together.

Next, step S904 is performed to enable the single level read mode. The specific reading manner of the single level read mode may be understood with reference to the foregoing description. In some embodiments, before obtaining the statistical result, the processor 1063 of the memory controller is configured to send a single level read mode set command to the memory device; the memory device 104 is configured to: enter a single level read mode in response to the mode set command, and obtain a statistical result corresponding to the first read voltage in the single level read mode.

Next, step S905 is performed to obtain a statistical result N. Here, the obtained statistical result N may include a first number N1 and/or a second number N2, and the obtained statistical result needs to correspond to the foregoing preset threshold. The processor 1063 of the memory controller may obtain a statistical result N fed back by the memory device.

Next, step S906 is performed to compare the obtained statistical result N with a preset threshold M.

Next, step S907 is performed to determine which of the statistical result N and the preset threshold M is larger.

When the statistical result N is greater than the preset threshold M, it instructs that the read disturb problem of the stored data in the physical page is relatively serious, the probability of failure of the soft decoding operation is higher, and it is necessary to enter a more complex error correction process, and at this time, the step S908 is performed to determine the data read disturb of the stored data in the physical page to be inferior, that is, the first read disturb state.

When the statistical result N is less than or equal to the preset threshold M, it instructs that the read disturb problem of the stored data in the physical page is still within the acceptable range, the probability of failure of the soft decoding operation is lower, and it is unnecessary to enter a more complex error correction process, and at this time, the step S909 is performed to determine the read disturb state of the stored data in the physical page to be non-inferior, that is, the second read disturb state.

After step S908 or step S909 is performed, step S910 is performed, and a test result is returned, that is, the determined result is output for other control processes to make respective decisions. For example, it is determined to trigger the garbage collection operation according to the read disturb, that is, whether to perform the data migration operation. In some embodiments, the data migration operation is performed on the physical page according to the read disturb state of the physical page being the first read disturb state. Therefore, only the state of the lowest two storage states need to be checked in the read scrub process, and the situation that garbage collection is triggered mistakenly due to read disturb can be avoided.

After step S910 is performed, step S911 is performed to end the read disturb state determination process.

It should be noted that, after the garbage collection is triggered, the data migration of the memory cell where the physical page is located may be immediately performed, or the data of the memory cell where the physical page is located may be marked first, and then garbage collection may be performed with the marked data of other locations at a proper time.

In some embodiments, the statistical result includes a first number, and the preset threshold includes a first threshold; and the processor is configured to: determine that the physical page is inferior according to the first number being greater than the first threshold, that is, the first read disturb state; and determine that the physical page is non-inferior according to the first number being less than or equal to the first threshold, that is, the second read disturb state.

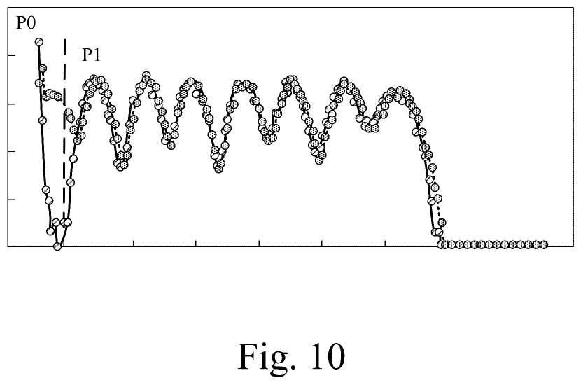

FIG. 10 shows a schematic diagram of threshold voltage distributions corresponding to exemplary storage states of a TLC. It should be noted that in FIG. 10, the horizontal coordinate is the threshold voltage, and the vertical coordinate is the number of memory cells; the curve of the solid line represents the threshold voltage distribution corresponding to each storage state when the data is written, and the curve of the dotted line represents the threshold voltage distribution corresponding to each storage state after the read disturb. In the following, a specific read disturb state determination operation flow will be described in detail with reference to FIG. 10. For example:
Step a1: Set the first read voltage to be a certain intermediate position of the first storage state P0 and the second storage state P1 (the position of the straight line example of the dotted line in FIG. 10).
Step a2: Set a comparison threshold, the comparison threshold may be a first threshold M1, and the first threshold may be a number of bits flipped in two read results under a second read voltage corresponding to the critical point at which the read disturb triggered soft decoding operation and a voltage near the second read voltage.
Step a3: Enable a single level read mode and set a read voltage of a read operation of the memory device to a first read voltage.
Step a4: Obtain, by the circuit operation in the memory device or external statistics, a number of bits flipped in two read results corresponding to a first read voltage and a voltage near the first read voltage that is, the first number N1.
Step a5: Compare with the set first threshold, if the first number N1 is greater than the first threshold M1, determine that the read disturb state of the stored data in the physical page is inferior, that is, the first read disturb status, and trigger the garbage collection operation at this time; and if the first number N1 is less than or equal to the first threshold M1, determine that the read disturb state of the stored data in the physical page is a non-inferior, that is, the second read disturb status, and no garbage collection operation needs to be triggered at this time.
Step a6: Return the test result. Here, the test result is the determined read disturb state.

In some embodiments, the statistical result includes a second number, and the preset threshold includes a second threshold; the processor is configured to: determine that the physical page is inferior according to the second number being greater than the second threshold, that is, the first read disturb state; and determine that the physical page is non-inferior according to the second number being less than or equal to the second threshold, that is, the second read disturb state.

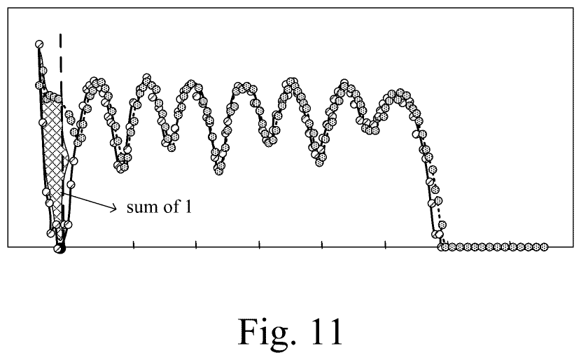

FIG. 11 shows a schematic diagram of threshold voltage distributions corresponding to exemplary storage states of a TLC. It should be noted that in FIG. 11, the horizontal coordinate is the threshold voltage, and the vertical coordinate is the number of memory cells; the curve of the solid line represents the threshold voltage distribution corresponding to each storage state when the data is written, and the curve of the dotted line represents the threshold voltage distribution corresponding to each storage state after the read disturb. In the following, a specific read disturb state determination operation flow will be described in detail with reference to FIG. 11. For example:
Step b1: Set the first read voltage to be a certain intermediate position of the first storage state P0 and the second storage state P1 (the position of the straight line example of the dotted line in FIG. 11).
Step b2: Set a comparison threshold, the comparison threshold may be a second threshold M2, and the second threshold may be a sum of the number of “1” on the left side of the second read voltage corresponding to the critical point at which the read disturb triggered soft decoding operation.
Step b3: Enable a single level read mode and set a read voltage of a read operation of the memory device to a first read voltage.
Step b4: Obtain the sum of the number of “1” on the left side of the first read voltage by the circuit operation in the memory device or external statistics, that is, the second number N2.
Step b5: Compare with the set second threshold, if the second number N2 is greater than the second threshold M2, determine that the read disturb state of the stored data in the physical page is inferior, that is, the first read disturb status, and trigger the garbage collection operation at this time; and if the second number N2 is less than or equal to the second threshold M2, determine that the read disturb state of the stored data in the physical page is a non-inferior, that is, the second read disturb status, and no garbage collection operation needs to be triggered at this time.
Step b6: Return the test result. Here, the test result is the determined read disturb state.

In some embodiments, the statistical result includes a first number and/or a second number, and the preset threshold includes a first threshold and a second threshold; the processor is configured to: determine that the physical page is inferior according to the first number being greater than the first threshold and the second number being greater than the second threshold, that is, the first read disturb state; and determine that the physical page is non-inferior according to the first number being less than or equal to the first threshold or according to the second number being less than or equal to the second threshold, that is, the second read disturb state.

In this embodiment, the specific read disturb state determination operation flow. For example:
Step c1: Set the first read voltage to be a certain intermediate position of the first storage state P0 and the second storage state P1 (the position of the straight line example of the dotted line in FIG. 11).
Step c2: Set a comparison threshold, the comparison threshold may be a first threshold M1 and a second threshold M2, where the first threshold may be a number of bits flipped in two read results under a second read voltage corresponding to the critical point at which the read disturb triggered soft decoding operation and a voltage near the second read voltage, and the second threshold may be a sum of the number of “1” on the left side of the second read voltage corresponding to the critical point at which the read disturb triggered soft decoding operation.
Step c3: Enable a single stage read mode and set a read voltage of a read operation of the memory device to a first read voltage.
Step c4: Obtain, by the circuit operation in the memory device, a number of bits flipped in two read results corresponding to a first read voltage and a voltage near the first read voltage, that is, the first number N1, and the sum of the number of “1” on the left side of the first read voltage, that is, the second number N2.
Step c5: Compare the first number with the first threshold, and compare the second number with the second threshold; if the first number N1 is greater than the first threshold M1 and the second number N2 is greater than the second threshold M2, determine that the read disturb state of the stored data in the physical page is inferior, that is, the first read disturb status, and trigger the garbage collection operation at this time; or if the first number N1 is less than or equal to the first threshold M1 or the second number N2 is less than or equal to the second threshold M2, determine that the read disturb state of the stored data in the physical page is a non-inferior, that is, the second read disturb status, and no garbage collection operation needs to be triggered at this time.
Step c6: Return the test result. Here, the test result is the determined read disturb state.

In the embodiments of the present disclosure, the read disturb state of the physical page is determined by obtaining the first number of bits flipped in two read results of the physical page corresponding to the first read voltage and the read voltage whose voltage difference with the first read voltage is less than the preset voltage, and/or the second number of bits of the physical page not successfully read using the first read voltage, and comparing the obtained data with a preset threshold. In the embodiments of the present disclosure, a direct comparison manner is simple, and a read disturb state of a physical page may be quickly determined without undergoing a complex decoding process such as LDPC; and the obtained first number and/or second number are both statistical results, a storage space occupied by the statistical results is relatively small, and a large number of I/O transmission are not required to obtain the statistical results, and a power consumption consumed in performing the determining process is relatively low. In addition, the scheme of the embodiment of the present disclosure is applied to the read scrub process, only the state of the lowest two storage states need to be checked, the situation that the garbage collection is triggered mistakenly due to read disturb can be avoided, the problem of read scrub time of the read disturb in the system level being longer can be effectively solved, and triggering the garbage collection operation mistakenly can be effectively avoided.

According to a second aspect, an embodiment of the present disclosure provides a memory system 102, as shown in FIG. 7, the memory system 102 includes: one or more memory devices 104; and a memory controller 106 according to an embodiment of the present disclosure, the memory controller 106 is coupled to the memory device 104 and controls the memory device 104.

In some embodiments, the composition structure of the memory system may refer to FIG. 7, and both the memory controller 106 and the memory device 104 included in the memory system 102 may be understood with reference to the foregoing description, and details are not described herein again. In some embodiments, the memory system may include a solid state disk.

In some embodiments, the memory controller 106 is configured to: in a process of performing read scrub on the memory device 104, send a first instruction, where the first instruction instructs to obtain a statistical result of the physical page; the memory device 104 is configured to: in response to the first instruction, obtain a statistical result of the physical page, and send the information including the statistical result of the physical page to the memory controller 106; the memory controller 106 is further configured to: determine whether the read disturb state of the physical page is inferior according to the statistical result and a preset threshold; and perform a data migration operation on the physical page according to the read disturb state of the physical page being inferior.

In the embodiment of the present disclosure, in the read scrub process, the memory device is used for obtaining the statistical result of the physical page under the first reading voltage, the obtained statistical result is transmitted to the memory controller, the processor of the memory controller executes the comparison of the statistical result with the preset threshold and the determination of the read disturb state of the physical page, and determine to whether to trigger the GC operation according to the determination result of the read disturb state, wherein the data migration operation is performed on the physical page according to the read disturb state of the physical page being inferior. According to the embodiment of the present disclosure, the way of determining the read disturb state is simple, fast and low in power consumption; only the state of the lowest two storage states need to be checked, the situation that the garbage collection is triggered mistakenly due to read disturb can be avoided, the problem of read scrub time of the read disturb in the system level being longer can be effectively solved, and triggering the garbage collection operation mistakenly can be effectively avoided.

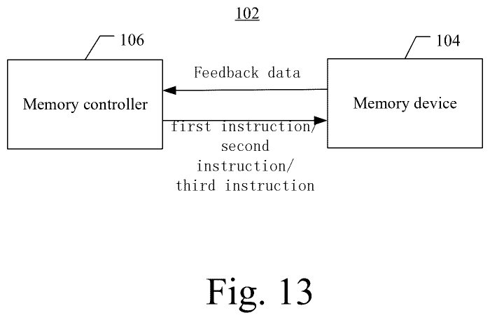

In some embodiments, as shown in FIG. 13, the memory controller 106 sends a first command to the memory device 104, and the memory device 104 feeds back a statistical result corresponding to the first read voltage in response to the first command.

According to a third aspect, an embodiment of the present disclosure provides a memory device 104, where the memory device 104 includes: a plurality of word lines; each word line is coupled to a plurality of memory cells, and the plurality of memory cells form at least one physical page; the peripheral circuit 302 coupled to the plurality of word lines and configured to: obtain a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determine a read disturb state of the physical page according to the statistical result.

It should be noted that the difference between this embodiment and the foregoing embodiment lies in that: the peripheral circuit of the memory device (more specifically, the control logic of the peripheral circuit) performs a comparison of the statistical result with the preset threshold and a determination of the read disturb state of the physical page.

Here, the structure of the memory device 104 may refer to FIG. 3B, and details are not described herein again.

In some embodiments, the peripheral circuit is further configured to: determine whether the read disturb state of the physical page is inferior according to a relationship between the statistical result and a preset threshold; and perform a data migration operation on the physical page based on the read disturb state of the physical page being determined to be inferior.

In some embodiments, the preset threshold includes a first threshold and/or a second threshold; and the peripheral circuit is configured to: determine that the read disturb state of the physical page is inferior according to the first number being greater than the first threshold and/or according to the second number being greater than the second threshold.

In some embodiments, the peripheral circuit is configured to: determine that the read disturb state of the physical page is non-inferior according to the first number being less than or equal to the first threshold and/or according to the second number being less than or equal to the second threshold.

In some embodiments, the first threshold includes a number of bits flipped in the two read results under a second read voltage corresponding to the read disturb triggered soft decoding enabled and a read voltage whose voltage difference with the second read voltage is less than a preset voltage; and the second threshold includes a number of bits read unsuccessfully under a second read voltage corresponding to the read disturb triggered soft decoding enable.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage

In some embodiments, the memory cell includes a plurality of memory bits, and the multi-bit storage data of the memory cell is read by multi-level read voltages; the peripheral circuit is configured to: set a read mode to a single level read mode before obtaining the statistical result of the physical page corresponding to the first read voltage; and the single level read mode includes reading at least one bit of storage data stored in the memory cell through a first level read voltage.

Here, the first read voltage, the preset voltage, the second read voltage, the first number, the second number, the first threshold, and the second threshold involved in this embodiment may all be understood with reference to the related description in the foregoing embodiments, and details are not described herein again.

In some embodiments, the peripheral circuit is configured to: obtain the first read voltage and the preset threshold.

Here, the first read voltage and the preset threshold may be stored in the memory cell of the specified area of the memory device first according to the foregoing setting principle, and the peripheral circuit of the memory device may directly obtain the first read voltage and the preset threshold from the memory cell of the specified area.

In some embodiments, the peripheral circuit is configured to: when the memory device is powered on, obtain a first read voltage and a preset threshold from the memory cell respectively; the first read voltage and the preset threshold are both fixed values.

In some embodiments, the peripheral circuit is configured to: when the memory device is powered on, obtain an initial value of the first read voltage and an initial value of the preset threshold from the memory cell respectively; and modify the initial value of the first read voltage and/or the initial value of the preset threshold by setting the feature command to obtain the first read voltage and the preset threshold.

In some embodiments, the plurality of memory cells coupled to each word line form a plurality of physical pages; the plurality of physical pages includes a plurality of target physical pages; the peripheral circuit is configured to: apply the first read voltage to a selected word line of the plurality of word lines; for each target physical page of the plurality of target physical pages coupled to the selected word line, determine a read disturb state of the respective target physical page according to a statistical result corresponding to the respective target physical page corresponding to the first read voltage; and float the selected word line after completing the read disturb state of all target physical pages coupled to the selected word line.

In some embodiments, each word line forms one or more physical pages with a plurality of memory cells coupled to one memory string, and a number of physical pages formed by all memory cells coupled to each word line is related to a number of bits stored in the memory cell and a number of memory strings included in the memory block. When there are a plurality of bits stored in the memory cell, each word line forms a plurality physical pages with a plurality of memory cells coupled to one memory string, and there is one target physical page in the plurality of physical pages, that is, each memory string corresponds to one target physical page. Here, the target physical page is related to a set voltage value of the first read voltage, and is not a fixed physical page. When the first read voltage relates to a threshold interval corresponding to the first storage state and the second storage state, the target physical page is a physical page corresponding to a memory bit used to distinguish between the first storage state and the second storage state, for example, the foregoing lower page.

For example, if the memory cell is TLC, and the number of memory strings included in the memory block is 6, a number of physical pages formed by all memory cells coupled to each word line is 18, and there are 6 target physical pages corresponding to the 6 memory strings in the 18 physical pages.

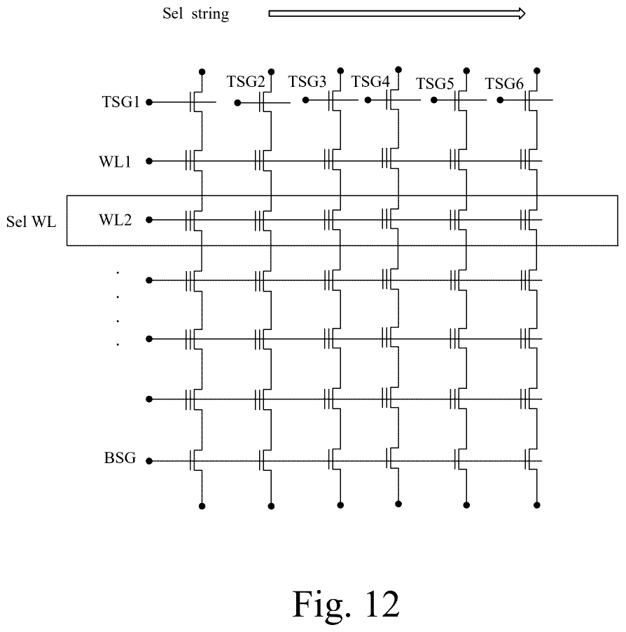

In the embodiment of the present disclosure, read disturb states of all memory cell columns of an entire word line may be performed once, FIG. 12 shows a schematic diagram of an exemplary memory device including a plurality of word lines and a plurality of top select gate TSGs, where one top select gate TSG controls whether a corresponding string is selected or not. In the following, a specific read disturb state determination operation flow will be described in detail with reference to FIG. 12. For example:
Step d1: Set the first read voltage N.
Step d2: Set a preset threshold M for comparison, and the preset threshold may be adjusted by setting a feature command.
Step d3: Enable a single level reading mode.
Step d4: Apply a set first read voltage to the selected word line.
Step d5: Obtain a statistical result of the physical page corresponding to the current memory string corresponding to the first read voltage, for example, the first number N. In this case, the voltage applied to the TSG coupled to the current string is the select voltage, and the voltage applied to the TSG coupled to the remaining string is the deselect voltage.

In step d6, Compare N with M, if N>M, the read disturb state of the memory cell coupled to the current memory string is inferior, that is, the first read disturb state, which may be marked as “1”; otherwise, the read disturb state of the current string is non-inferior, that is, the second read disturb state, which may be marked as “0”.
Step d7: Maintain the application of the first read voltage to the selected word line, and switch to the next string of the selected word line. For example, the voltage applied to the TSG coupled to the current string is changed from the select voltage to the deselect voltage, the voltage applied to the TSG coupled to the next string is changed from the deselect voltage to the select voltage, and the voltage applied to the TSG coupled to the remaining string remains the deselect voltage.
Step d8: Repeat steps d5-d7 to obtain read disturb states of all strings of the selected word line.
Step d9: Float the selected word line.
Step d10: Return the test result. Here, the test result is the determined read disturb states of all strings of the selected word line.

In some embodiments, if there are both “1” and “0” in the determined read disturb states of the strings included in the entire word line, or as long as there is “1”, the entire word line feeds back “1”, that is, data migration needs to be performed on the data of the memory cell coupled to the entire word line.

In some embodiments, if there are both “1” and “0” in the determined read disturb states of the strings included in the entire word line, the read disturb state map of the string of the entire word line can be made to feed back the read disturb states of all the string in detail, and finally, whether to perform data migration can be determined according to the corresponding algorithm.

In some embodiments, the statistical result includes a first number; the peripheral circuit is configured to: read the stored data of the physical page corresponding to the first read voltage to obtain a first result; adjust the first read voltage to obtain an adjusted read voltage, and read the stored data of the physical page under the adjusted read voltage to obtain a second result; perform a logical operation on the first result and the second result to obtain a third result; and count the number of bits in the third result that represent that the second result is flipped relative to the first result to obtain the first number.

In some embodiments, the peripheral circuit includes: a first latch configured to store the first result; a second latch configured to store the second result; and a third latch configured to store the third result.

Here, the memory device is used as an execution body to generate the first number, and the memory device may generate the first number by using the latches in its page buffer, specifically, store a first result corresponding to the first read voltage in the first latch; store a second result under a read voltage after the first read voltage is adjusted according to a preset step (here, the preset step may be slightly less than the forgoing preset voltage, such as 5 mV to 20 mV, for example, the preset step may be 5 mV, 10 mV, 15 mV, 20 mV) in the second latch; and perform an XOR logical operation on the first result and the second result by using the third latch to obtain the first number. The first number may be directly used by the peripheral circuit, or the first number may be buffered first to the cache latch and then sent to the memory controller from the cache latch.

In this way, the read data (the first result) corresponding to the first read voltage can be directly used to be stored in the page buffer, and the XOR operation is performed on the data and the read data (the second result) under a voltage near the first read voltage in the page buffer, no additional operation is required, no extra buffer space is required, and the scheme is simple.

In the embodiment of the present disclosure, through the circuit operation (the operation of the page buffer), the degree of progress of the read disturb of the memory cell of the memory device is quickly determined, so as to determine whether to trigger the GC or not, the memory device quickly obtains the number of flips of the two read results corresponding to the first read voltage and a voltage near the first read voltage through the circuit operation, and then compares it with the set preset threshold; if the number is greater than the set preset threshold, the read disturb state is determined to be the first read disturb state, and the GC is required to be triggered; otherwise, the read disturb state is determined to be the second read disturb state, and the GC is not required to be triggered. In this way, the speed of determining the read disturb state is greatly improved (taking QLC as an example, the spent time is reduced from about 100 us to about 50 us), while the power consumed in the whole process is small due to the amount of data interaction being small, facilitating the reduction of power consumption of the system.

According to a fourth aspect, an embodiment of the present disclosure provides a memory system 102, where the memory system includes: one or more memory devices 104 provided in an embodiment of the present disclosure; and a memory controller 106, coupled to the memory device 104 and configured to control the memory device 104.

In some embodiments, the composition structure of the memory system may refer to FIG. 7, and both the memory controller 106 and the memory device 104 included in the memory system 102 may be understood with reference to the foregoing description, and details are not described herein again. In some embodiments, the memory system may include a solid state disk.

It should be noted that the memory system in this embodiment differs from the memory system in the foregoing embodiments in that: in the memory system in the foregoing embodiment, a memory controller performs a comparison of a statistical result with a preset threshold and determination of a read disturb state of a physical page; in the memory system according to the embodiment, a peripheral circuit of the memory device performs a comparison of a statistical result with a preset threshold and determination of a read disturb state of a physical page.

In some embodiments, the memory controller 106 is configured to: in a process of performing read scrub on the memory device, send a second instruction, where the second instruction instructs to obtain a read disturb state of the physical page; the memory device 104 is configured to: in response to the second instruction, obtain a statistical result of the physical page corresponding to the first read voltage, and determine whether the read disturb state of the physical page is inferior according to a relationship between the statistical result and the preset threshold; and send information including the read disturb state of the physical page to the memory controller 106; and the memory controller 106 is further configured to: perform a data migration operation on the physical page according to the read disturb state of the physical page being inferior.

In the embodiment of the present disclosure, in the read scrub process, a memory device is used for obtaining a statistical result of one physical page of a word line corresponding to a first read voltage and performing a comparison of the statistical result with a preset threshold and determination of a read disturb state of the physical page, and sending the determination result to a memory controller, and the memory controller determines whether to trigger a GC operation according to the determination result.

In some embodiments, the memory controller 106 is configured to: in a process of performing read scrub on the memory device, send a third instruction, wherein the third instruction instructs to obtain a read disturb state of all physical pages coupled to the word line; the memory device 104 is configured to: in response to the third instruction, obtain a statistical result corresponding to all target physical pages coupled to the word line corresponding to the first read voltage, and determine whether the read disturb state of target physical page is inferior according to a relationship between the statistical result and the preset threshold; and send information including the read disturb state of all target physical pages coupled to the word line to the memory controller 106; and the memory controller 106 is further configured to: perform a data migration operation on all target physical pages coupled to the word line according to all target physical pages coupled to the word line being inferior.

That is, the data migration operation is performed on all memory cells coupled to the word line according to all target physical pages coupled to the word line being inferior.

In the embodiment of the present disclosure, in the read scrub process, the memory device is used for obtaining a statistical result of all target physical pages of a word line corresponding to a first read voltage and performing a comparison of the statistical result with a preset threshold and determination of a read disturb state of the physical page, and sending the determination result to a memory controller, and the memory controller determines whether to trigger a GC operation according to the determination result.

In some embodiments, as shown in FIG. 13, the memory controller 106 sends a second or third command to the memory device 104, which feeds back read disturb states of different magnitudes of data in response to different commands.

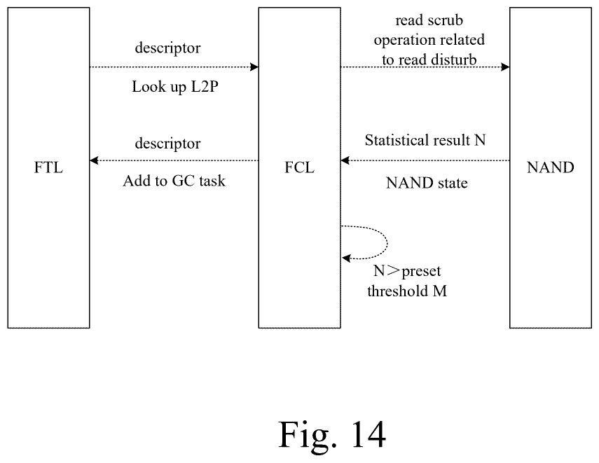

FIG. 14 is a schematic flowchart of an exemplary read scrub operation related to read disturb according to an embodiment of the present disclosure. A flash translation layer (FTL), a flash control layer (FCL), and a flash memory are shown in FIG. 14. Here, the FTL is mainly configured to complete translation or mapping of the logical address space of the host to the physical address space of the flash memory, and further needs to perform some processes for flash memory characteristics, such as garbage collection, bad block management, wear leveling, read disturb problem processing, data retention problem processing, etc. The FCL is connected between the FTL and the flash memory for managing data stored in the flash memory. The read scrub process of read disturb includes: the FTL performs transition from the logical address space of the host to the physical address of the flash memory, the FCL sends the physical address of the flash memory to be read scrub to the flash memory, the flash memory feeds back the statistical result N corresponding to the first read voltage to the FCL, the FCL compares the feedback statistical result N with the preset threshold M, and if N>M, feeds back the corresponding physical address to the FTL, and the FTL adds the physical address to the task which will perform garbage collection.

It should be noted that the FTL and the FLC may be located inside the memory controller; or the FTL is located on the host side, and the FLC is located in the memory device (flash memory).

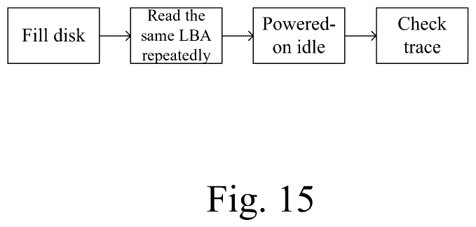

FIG. 15 is a schematic flowchart of an exemplary process related to testing the read scrub of read disturb according to an embodiment of the present disclosure. As shown in FIG. 15, the following steps are performed:
Step e1: Fill disk. Here, the fill disk may be understood to write full data to the storage space in the memory device of the memory system.
Step e2: Read the same logical block address (LBA) repeatedly. Here, reading the same logical block address repeatedly may shorten the occurrence time of the read disturb problem.
Step e3: Power-on idle. Here, the power-on idle may be understood to power on the memory system, and when the memory system is in an idle state, the read scrub operation related to read disturb provided in the embodiments of the present disclosure is performed.
Step e4: Trace. Here, the trace may be understood to at least trace an event log of a tracer during the read scrub operation performed by the tracer.

In the trace of step e4, it can be found that in the whole process: 1. the SLR is enabled, and after the read command (for example, 00h_addr_30h) is issued, there is no large amount of data transmission on the IO bus; 2. the duration of the R/B pin in the busy state is less than the duration of the conventional read operation; and 3, some data may be migrated to other positions subsequently (when the data is read, the physics corresponding to these data changes before and after read scrub).

According to a fifth aspect, an embodiment of the present disclosure provides an operating method of a memory controller, wherein the memory controller is coupled to at least one memory device, and the memory device includes a plurality of word lines. Each word line is coupled to a plurality of memory cells, and the plurality of memory cells form at least one physical page; the method comprises: obtaining a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determining a read disturb state of the physical page according to the statistical result.

In some embodiments, the determining a read disturb state of the physical page according to the statistical result includes: determining whether the read disturb state of the physical page is inferior according to a relationship between the statistical result and a preset threshold; and the method further includes: performing a data migration operation on the physical page based on the read disturb state of the physical page being determined to be inferior.

In some embodiments, the preset threshold includes a first threshold and/or a second threshold; and determining whether the read disturb state of the physical page is inferior according to a relationship between the statistical result and a preset threshold includes: determining that the read disturb state of the physical page is inferior according to the first number being greater than the first threshold and/or according to the second number being greater than the second threshold.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the memory cell includes a plurality of memory bits, and the multi-bit storage data of the memory cell is read by multi-level read voltages; and the method further includes: setting a read mode to a single level read mode before obtaining the statistical result of the physical page corresponding to the first read voltage; and the single level read mode includes reading at least one bit of storage data stored in the memory cell through a first level read voltage.

In some embodiments, the obtaining a statistical result of the physical page corresponding to the first read voltage includes: receiving the statistical result of the physical page corresponding to the first read voltage transmitted from the memory device; or receiving read results of the physical page corresponding to the first read voltage and the second read voltage respectively or the read result of the physical page corresponding to the first read voltage transmitted from the memory device; and performing operations and statistics on the read results to obtain a statistical result. In some embodiments, the method further includes: obtaining the first read voltage and the preset threshold respectively.

In some embodiments, the obtaining the first read voltage and the preset threshold respectively includes: when the memory controller is powered on, obtaining the first read voltage and the preset threshold from the memory device respectively, wherein the first read voltage and the preset threshold are both fixed values.

In some embodiments, the obtaining the first read voltage and the preset threshold respectively includes: when the memory controller is powered on, obtaining an initial value of the first read voltage and an initial value of the preset threshold from the memory device respectively; and modifying the initial value of the first read voltage and/or the initial value of the preset threshold by setting a feature command to obtain the first read voltage and the preset threshold.

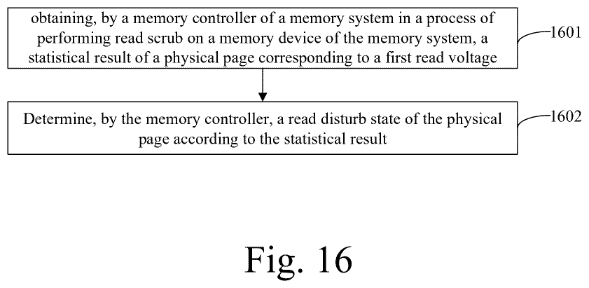

According to a sixth aspect, an embodiment of the present disclosure provides an operating method of a memory system, as shown in FIG. 16.
Step 1601: A memory controller of a memory system obtains a statistical result of a physical page corresponding to a first read voltage in a process of performing read scrub on a memory device of a memory system; the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; the memory device includes a plurality of word lines and a plurality of memory cells coupled to each word line, and the plurality of memory cells form at least one physical page.
Step 1602: The memory controller determines the read disturb state of the physical page according to the statistical result.

In some embodiments, determining the read disturb state of the physical page according to the statistical result includes: determining, by the memory controller, whether the read disturb state of the physical page is inferior according to a relationship between the statistical result and a preset threshold; and the method further includes: performing a data migration operation on the physical page based on the read disturb state of the physical page being determined to be inferior.

In some embodiments, the preset threshold includes a first threshold and/or a second threshold; and determining whether the read disturb state of the physical page is inferior according to a relationship between the statistical result and a preset threshold includes: determining that the read disturb state of the physical page is inferior according to the first number being greater than the first threshold and/or according to the second number being greater than the second threshold.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the memory cell includes a plurality of memory bits, and the multi-bit storage data of the memory cell is read by multi-level read voltages; and the method further includes: setting a read mode to a single level read mode before obtaining the statistical result of the physical page corresponding to the first read voltage; and the single level read mode includes reading at least one bit of storage data stored in the memory cell through a first level read voltage.

In some embodiments, the obtaining a statistical result of the physical page corresponding to the first read voltage includes: receiving the statistical result of the physical page corresponding to the first read voltage transmitted from the memory device; or receiving read results of the physical page corresponding to the first read voltage and the second read voltage respectively or the read result of the physical page corresponding to the first read voltage transmitted from the memory device; and performing operations and statistics on the read results to obtain a statistical result. In some embodiments, the method further includes: obtaining the first read voltage and the preset threshold respectively.

In some embodiments, the obtaining the first read voltage and the preset threshold respectively includes: when the memory controller is powered on, obtaining the first read voltage and the preset threshold from the memory device respectively, wherein the first read voltage and the preset threshold are both fixed values.

In some embodiments, the obtaining the first read voltage and the preset threshold respectively includes: when the memory controller is powered on, obtaining an initial value of the first read voltage and an initial value of the preset threshold from the memory device respectively; and modifying the initial value of the first read voltage and/or the initial value of the preset threshold by setting a feature command to obtain the first read voltage and the preset threshold.

According to a seventh aspect, an embodiment of the present disclosure provides an operating method of a memory device, wherein the memory device includes a plurality of word lines; each word line is coupled to a plurality of memory cells, and the plurality of memory cells form at least one physical page; and the method includes:

Obtaining a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page; and determining a read disturb state of the physical page according to the statistical result.

In some embodiments, determining, by the memory device, the read disturb state of the physical page according to the statistical result includes: determining whether the read disturb state of the physical page is inferior according to a relationship between the statistical result and a preset threshold; and the method further includes: performing a data migration operation on the physical page whose read disturb state is determined to be inferior.

In some embodiments, the preset threshold includes a first threshold and/or a second threshold; and determining whether the read disturb state of the physical page is inferior according to a relationship between the statistical result and a preset threshold includes: determining that the read disturb state of the physical page is inferior according to the first number being greater than the first threshold and/or according to the second number being greater than the second threshold.

In some embodiments, the plurality of storage states of the physical page includes the storage state with the highest mean value of the threshold voltage intervals; the first read voltage is greater than a mean value of a threshold voltage interval corresponding to a highest storage state of the physical page when the data is written.

In some embodiments, the plurality of storage states include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the method further includes: obtaining the first read voltage and the preset threshold respectively.

In some embodiments, the obtaining the first read voltage and the preset threshold respectively includes: when the memory device is powered on, obtaining the first read voltage and the preset threshold from the memory cell respectively, wherein the first read voltage and the preset threshold are both fixed values.

In some embodiments, the obtaining the first read voltage and the preset threshold respectively includes: when the memory device is powered on, obtaining an initial value of the first read voltage and an initial value of the preset threshold from the memory cell respectively; and modifying the initial value of the first read voltage and/or the initial value of the preset threshold by setting a feature command to obtain the first read voltage and the preset threshold.

In some embodiments, the plurality of memory cells coupled to each word line form a plurality of physical pages; the plurality of physical pages includes a plurality of physical pages; the method further includes: applying the first read voltage to a selected word line of the plurality of word lines; for each target physical page of the plurality of target physical pages coupled to the selected word line, determining a read disturb state of the respective target physical page according to a statistical result corresponding to the respective target physical page corresponding to the first read voltage; and floating the selected word line after completing the read disturb state of all target physical pages coupled to the selected word line.

In some embodiments, the statistical result includes a first number; the obtaining the first number includes: reading the stored data of the physical page corresponding to the first read voltage to obtain a first result; adjusting the first read voltage to obtain an adjusted read voltage, and reading the stored data of the physical page under the adjusted read voltage to obtain a second result; performing a logical operation on the first result and the second result to obtain a third result; and counting the number of bits in the third result that represent that the second result is flipped relative to the first result to obtain the first number.

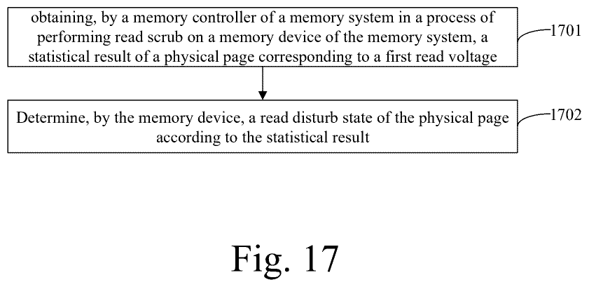

According to an eighth aspect, an embodiment of the present disclosure provides an operating method of a memory system, as shown in FIG. 17, the operating method of the memory system includes:
Step 1701: In a process in which a memory controller of a memory system performs read scrub on a memory device of a memory system, obtain a statistical result of a physical page corresponding to a first read voltage, wherein the statistical result includes a first number of bits flipped in two read results of the physical page corresponding to the first read voltage and a read voltage whose voltage difference with the first read voltage is less than a preset voltage, and/or a second number of bits of the physical page not successfully read using the first read voltage; the first read voltage is less than a mean value of a threshold voltage interval corresponding to an intermediate storage state of the physical page. The memory device includes a plurality of word lines and a plurality of memory cells coupled to each word line, and the plurality of memory cells form at least one physical page.
Step 1702: The memory device determines a read disturb state of the physical page according to the statistical result.

In some embodiments, the determining, by the memory device, the read disturb state of the physical page according to the statistical result includes: determining, by the memory device, whether the read disturb state of the physical page is inferior according to a relationship between the statistical result and a preset threshold; and the method further includes: performing, by the memory controller, a data migration operation on the physical page according to the read disturb state of the physical page being the first read disturb state.

In some embodiments, the preset threshold includes a first threshold and/or a second threshold; and determining whether the read disturb state of the physical page is inferior according to a relationship between the statistical result and a preset threshold includes: determining that the read disturb state of the physical page is inferior according to the first number being greater than the first threshold and/or according to the second number being greater than the second threshold.

In some embodiments, the plurality of storage states of the physical page include a first storage state and a second storage state whose mean value of the threshold voltage interval is the lowest; the first threshold voltage is a mean value of a threshold voltage interval corresponding to the first storage state when the physical page is writing data; the second threshold voltage is a mean value of a threshold voltage interval corresponding to the second storage state when the physical page is writing data; and the first read voltage is between the first threshold voltage and the second threshold voltage.

In some embodiments, the memory cell includes a plurality of memory bits, and the multi-bit storage data of the memory cell is read by multi-level read voltages; and the method further includes: setting a read mode to a single level read mode before obtaining the statistical result of the physical page corresponding to the first read voltage; and the single level read mode includes reading at least one bit of storage data stored in the memory cell through a first level read voltage.

In some embodiments, the method further includes: obtaining the first read voltage and the preset threshold respectively.

In some embodiments, the obtaining the first read voltage and the preset threshold respectively includes: when the memory device is powered on, obtaining the first read voltage and the preset threshold from the memory cell respectively, wherein the first read voltage and the preset threshold are both fixed values.

In some embodiments, the obtaining the first read voltage and the preset threshold respectively includes: when the memory device is powered on, obtaining an initial value of the first read voltage and an initial value of the preset threshold from the memory cell respectively; and modifying the initial value of the first read voltage and/or the initial value of the preset threshold by setting a feature command to obtain the first read voltage and the preset threshold.

In some embodiments, the plurality of memory cells coupled to each word line form a plurality of physical pages; the plurality of physical pages includes a plurality of physical pages; the method further includes: applying the first read voltage to a selected word line of the plurality of word lines; for each target physical page of the plurality of target physical pages coupled to the selected word line, determining a read disturb state of the respective target physical page according to a statistical result corresponding to the respective target physical page corresponding to the first read voltage; and floating the selected word line after completing the read disturb state of all target physical pages coupled to the selected word line.

In some embodiments, the statistical result includes a first number; the obtaining the first number includes: reading the stored data of the physical page corresponding to the first read voltage to obtain a first result; adjusting the first read voltage to obtain an adjusted read voltage, and reading the stored data of the physical page under the adjusted read voltage to obtain a second result; performing a logical operation on the first result and the second result to obtain a third result; and counting the number of bits in the third result that represent that the second result is flipped relative to the first result to obtain the first number.

According to a ninth aspect, an embodiment of the present disclosure provides a computer-readable storage medium, where the computer-readable storage medium stores a computer program, and when the computer program is executed by a processor, steps of the operation method provided in the embodiments of the present disclosure are implemented.

In some embodiments, the storage medium may be a magnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, an optical disk, or a compact disc read-only memory (CD-ROM), or the like; or may be various devices including one or any combination of the foregoing memory devices.

In some embodiments, the executable instructions may be written in the form of a program, software, software module, script, or code, may be written in any form of programming language (including compiled or interpreted languages, or declarative or procedural languages), and may be deployed in any form, including being deployed as a standalone program or as a module, component, subroutine, or other unit suitable for use in a computing environment.

As an example, executable instructions may, but need not, correspond to files in a file system, may be stored in a portion of a file that stores other programs or data, for example, in one or more scripts stored in a hypertext markup language (HTML) document, in a single file dedicated to the program in question, or in multiple collaborative files (e.g., files that store one or more modules, subroutines, or portions of code).

As an example, executable instructions may be deployed for execution on one electronic device, or on multiple electronic devices located at one location, or alternatively on multiple electronic devices distributed at multiple locations and interconnected by a communication network.

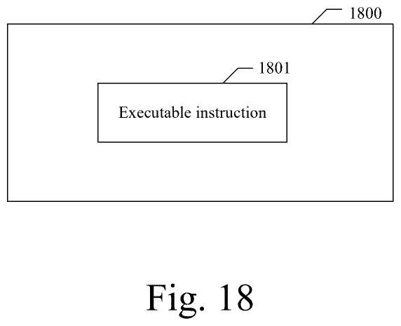

FIG. 18 is a schematic block diagram of a readable storage medium according to an embodiment of the present disclosure. An embodiment of the present disclosure provides a readable storage medium, where the storage medium 1800 stores executable instructions 1801, and when the executable instructions 1801 are executed by a processor, the operating method of the memory system in the foregoing technical solutions may be implemented. The operating method comprises the following steps: a memory controller of a memory system obtains a statistical result of a physical page corresponding to a first read voltage in a process of performing read scrub on a memory device of the memory system; the memory controller or the memory device determines the read disturb state of the physical page according to a relationship between the statistical result and a preset threshold; and the memory controller performs a data migration operation on the physical page according to the read disturb state of the physical page being the first read disturb state.

It should be understood that “one embodiment” or “an embodiment” mentioned throughout the specification means that a specific feature, structure, or characteristic related to the embodiment is included in at least one embodiment of the present disclosure. Thus, “in one embodiment” or “in an embodiment” appearing throughout the specification need not necessarily refer to the same embodiment. Further, these particular features, structures, or characteristics may be incorporated in one or more embodiments in any suitable manner. It should be understood that, in various embodiments of the present disclosure, the sequence numbers of the foregoing processes do not mean a sequence of execution sequences, and an execution sequence of each process should be determined by function and intrinsic logic thereof, and should not constitute any limitation on an implementation process of the embodiments of the present disclosure. The foregoing sequence numbers of the embodiments of the present disclosure are merely for description, and do not represent the advantages or disadvantages of the embodiments.

The above description is only an example implementation of the present disclosure, and is not intended to limit the scope of the present disclosure, and any equivalent structural transformation made by using the present disclosure and the accompanying drawings or any direct/indirect application of the present disclosure to other related technical fields is included within the scope of the present disclosure.

What is claimed is:

1. A memory controller coupled to at least one memory device, wherein the memory device includes a plurality of word lines, each word line is coupled to a plurality of memory cells, and the plurality of memory cells form at least one physical page;
the memory controller includes: a processor, configured to:
obtain a statistical result of a physical page corresponding to a first read voltage, wherein the statistical result includes at least one of a first number of bits flipped between two read results of the physical page corresponding to the first read voltage and a read voltage having a voltage difference of less than a preset voltage with the first read voltage, or a second number of bits of the physical page not successfully read using the first read voltage, and wherein the first read voltage is less than a mean value of a threshold voltage interval corresponding to an intermediate storage state of the physical page; and
determine a read disturb state of the physical page according to the statistical result.

2. The memory controller of claim 1, wherein the processor is further configured to:
determine whether the read disturb state of the physical page is inferior according to a relationship between the statistical result and a preset threshold; and
perform a data migration operation on the physical page based on determining that the read disturb state of the physical page is inferior.

3. The memory controller of claim 2, wherein the preset threshold includes at least one of a first threshold or a second threshold; and the processor is configured to:
determine that the read disturb state of the physical page is inferior according to at least one of the first number being greater than the first threshold or the second number being greater than the second threshold.

4. The memory controller of claim 1, wherein a plurality of storage states of the physical page include a first storage state and a second storage state having a threshold voltage interval with the lowest mean value; and
wherein the first read voltage is between a first threshold voltage and a second threshold voltage, the first threshold voltage is a mean value of a threshold voltage interval corresponding to the first storage state when the physical page is writing data, and the second threshold voltage is a mean value of a threshold voltage interval corresponding to the second storage state when the physical page is writing data.

5. The memory controller of claim 1, wherein a memory cell of the memory cells includes a plurality of memory bits, and multi-bit stored data of the memory cell is read by multi-level read voltages, and the processor is configured to:
set a read mode to a single-level read mode before obtaining the statistical result of the physical page corresponding to the first read voltage, and the single-level read mode includes reading at least one bit of stored data in the memory cell by one level read voltage.

6. The memory controller of claim 1, wherein the memory controller further includes an interface coupled to the processor; and
the interface is configured to: receive, from the memory device, the statistical result of the physical page corresponding to the first read voltage; or
the interface is configured to: receive, from the memory device, read results of the physical page corresponding to the first read voltage and a second read voltage respectively, or the read result of the physical page corresponding to the first read voltage; and the processor is configured to: perform operations and statistics on the read results to obtain a statistical result.

7. The memory controller of claim 2, wherein the processor is configured to:
obtain the first read voltage and the preset threshold respectively.

8. The memory controller of claim 7, wherein the processor is configured to:
when the memory controller is powered on, obtain the first read voltage and the preset threshold respectively from the memory device, wherein both the first read voltage and the preset threshold are fixed values.

9. The memory controller of claim 7, wherein the processor is configured to:
when the memory controller is powered on, obtain an initial value of the first read voltage and an initial value of the preset threshold respectively from the memory device; and
modify, by setting a feature command, at least one of the initial value of the first read voltage or the initial value of the preset threshold to obtain the first read voltage and the preset threshold.

10. A memory system, including:
one or more memory devices; and
a memory controller, coupled to the one or more memory devices and configured to control the one or more memory devices, wherein a memory device of the one or more memory devices includes a plurality of word lines, each word line is coupled to a plurality of memory cells, and the plurality of memory cells form at least one physical page;
the memory controller includes: a processor configured to:
obtain a statistical result of a physical page corresponding to a first read voltage, wherein the statistical result includes at least one of a first number of bits flipped between two read results of the physical page corresponding to the first read voltage and a read voltage having a voltage difference of less than a preset voltage with the first read voltage, or a second number of bits of the physical page not successfully read using the first read voltage, and wherein the first read voltage is less than a mean value of a threshold voltage interval corresponding to an intermediate storage state of the physical page; and
determine a read disturb state of the physical page according to the statistical result.

11. The memory system of claim 10, wherein
the memory controller is configured to: in a process of performing a read scrub on the memory device, send a first instruction, wherein the first instruction instruct to obtain the statistical result of the physical page;
the memory device is configured to: in response to the first instruction, obtain the statistical result of the physical page, and send information including the statistical result of the physical page to the memory controller; and
the memory controller is further configured to: determine whether the read disturb state of the physical page is inferior according to the statistical result and a preset threshold, and perform a data migration operation on the physical page according to the read disturb state of the physical page being inferior.

12. A memory device, including:
a plurality of word lines,
each word line is coupled to a plurality of memory cells, and the plurality of memory cells form at least one physical page;
a peripheral circuit coupled to the plurality of word lines and configured to:
obtain a statistical result of a physical page corresponding to a first read voltage, wherein the statistical result includes at least one of a first number of bits flipped between two read results of the physical page corresponding to the first read voltage and a read voltage having a voltage difference of less than a preset voltage with the first read voltage, or a second number of bits of the physical page not successfully read using the first read voltage, and wherein the first read voltage is less than a mean value of a threshold voltage interval corresponding to an intermediate storage state of the physical page; and
determine a read disturb state of the physical page according to the statistical result.

13. The memory device of claim 12, wherein the peripheral circuit is further configured to:
determine whether the read disturb state of the physical page is inferior according to a relationship between the statistical result and a preset threshold, and a data migration operation is to be performed on the physical page for which the read disturb state is determined to be inferior.

14. The memory device of claim 13, wherein the preset threshold includes at least one of a first threshold or a second threshold; and the peripheral circuit is configured to:
determine that the first read disturb state of the physical page is inferior according to at least one of the first number being greater than the first threshold or the second number being greater than the second threshold.

15. The memory device of claim 12, wherein a plurality of storage states of the physical page include a first storage state and a second storage state having a threshold voltage interval with the lowest mean value; and
wherein the first read voltage is between a first threshold voltage and a second threshold voltage, the first threshold voltage is a mean value of a threshold voltage interval corresponding to the first storage state when the physical page is writing data, and the second threshold voltage is a mean value of a threshold voltage interval corresponding to the second storage state when the physical page is writing data.

16. The memory device of claim 12, wherein the memory cell includes a plurality of memory bits, and multi-bit stored data of the memory cell is read by multi-level read voltages; and the peripheral circuit is configured to:
set a read mode to a single-level read mode before obtaining the statistical result of the physical page corresponding to the first read voltage, and the single-level read mode includes reading at least one bit of stored data in the memory cell by one level read voltage.

17. The memory device of claim 13, wherein the peripheral circuit is configured to:
obtain the first read voltage and the preset threshold; and
when the memory device is powered on, obtain the first read voltage and the preset threshold respectively from the memory cell, wherein both the first read voltage and the preset threshold are fixed values.

18. The memory device of claim 17, wherein the peripheral circuit is configured to:
when the memory device is powered on, obtain an initial value of the first read voltage and an initial value of the preset threshold respectively from the memory cell; and
modify, by setting a feature command, at least one of the initial value of the first read voltage or the initial value of the preset threshold to obtain the first read voltage and the preset threshold.

19. The memory device of claim 12, wherein the plurality of memory cells coupled to the word line form a plurality of physical pages, and the plurality of physical pages includes a plurality of target physical pages;
the peripheral circuit is configured to:
apply the first read voltage to a selected word line of the plurality of word lines;
for each target physical page of the plurality of target physical pages coupled to the selected word line, determine a read disturb state of a respective target physical page according to the statistical result of the respective target physical page corresponding to the first read voltage; and
float the selected word line after completing the read disturb state of all of the target physical pages coupled to the selected word line.

20. The memory device of claim 12, wherein the statistical result includes a first number, and the peripheral circuit is configured to:
read stored data of the physical page using the first read voltage to obtain a first result;
adjust the first read voltage to obtain an adjusted read voltage, and read the stored data of the physical page using the adjusted read voltage to obtain a second result;
perform a logical operation on the first result and the second result to obtain a third result; and
count the number of bits in the third result that represent that the second result is flipped relative to the first result, to obtain the first number, wherein the peripheral circuit includes a first latch, a second latch, and a third latch, and wherein
the first latch is configured to store the first result;
the second latch is configured to store the second result; and
the third latch is configured to store the third result.
